(19) United States
(12) Patent Application Publication
(10) Pub. No.: US 2026/0227878 A1
(43) Pub. Date: Aug. 6, 2026

(54) ELECTROSTATIC-SENSING INPUT DEVICE

(71) Applicant: ALPS ALPINE CO., LTD., Tokyo (JP)

(72) Inventors: Takayuki SAIJO, Miyagi (JP); Shunsuke UMEMURA, Miyagi (JP)

(21) Appl. No.: 19/631,343

(22) Filed: Mar. 27, 2026

Related U.S. Application Data
(63) Continuation of application No. PCT/JP2024/035459, filed on Oct. 3, 2024.

(30) Foreign Application Priority Data
Oct. 6, 2023 (JP) 2023-174270

(51) Int. Cl. G06F 3/044; G01D 5/24

(52) U.S. Cl. CPC G06F 3/0444; G01D 5/24

(57) ABSTRACT

An electrostatic-sensing input device includes a touch input surface, wherein the touch input surface includes a first operation region overlapping a first electrode portion in a plan view, a first decorative portion having a line shape and a predetermined width, formed of a conductive material, and configured to overlap the first operation region in the plan view, a second operation region overlapping a second electrode portion in the plan view, and a second decorative portion having a line shape and a predetermined width, formed of a conductive material, and configured to overlap the second operation region in the plan view, and the first decorative portion and the second decorative portion are not connected to each other and are not electrically connected to another component.

### CROSS-REFERENCE TO RELATED APPLICATIONS

This application is a continuation of International Application No. PCT/JP 2024/035459, filed on Oct. 3, 2024 and designating the U.S., which claims priority to Japanese Patent Application No. 2023-174270, filed on Oct. 6, 2023. The contents of these applications are incorporated herein by reference in their entirety.

### TECHNICAL FIELD

The present disclosure relates to an electrostatic-sensing input device.

### BACKGROUND

Japanese Laid-open Patent Application Publication No. 2013-157142 (Patent Document 1) describes a capacitive input device including a touch plate and a decorative layer that decorates a surface of the touch plate. In the decorative layer, a first background color layer and a second background color layer are laminated on each other as layers for adding fundamental background colors or a shielding function to the decorative layer.

### SUMMARY OF THE INVENTION

An electrostatic-sensing input device according to one embodiment of the present disclosure includes a touch input surface, wherein the touch input surface includes a first operation region overlapping a first electrode portion in a plan view, a first decorative portion having a line shape and a predetermined width, formed of a conductive material, and configured to overlap the first operation region in the plan view, a second operation region overlapping a second electrode portion in the plan view, and a second decorative portion having a line shape and a predetermined width, formed of a conductive material, and configured to overlap the second operation region in the plan view, and the first decorative portion and the second decorative portion are not connected to each other and are not electrically connected to another component.

### BRIEF DESCRIPTION OF THE DRAWINGS

FIG. 1 is a perspective view of the exterior of an electrostatic-sensing input device according to an embodiment;

FIG. 2 is an exploded perspective view of the electrostatic-sensing input device according to the embodiment;

FIG. 3 is a perspective cross-sectional view illustrating a cross section, take along the YZ plane, of the electrostatic-sensing input device according to the embodiment;

FIG. 4 is a plan view of an input member included in the electrostatic-sensing input device according to the embodiment;

FIG. 5 is a plan view of a sensor sheet included in the electrostatic-sensing input device according to the embodiment;

FIG. 6A is a diagram illustrating the positional relationship between operation regions and electrode portions of the sensor sheet included in the electrostatic-sensing input device according to the embodiment;

FIG. 6B is a diagram illustrating the positional relationship between the operation regions and decorative portions of the input member included in the electrostatic-sensing input device according to the embodiment;

FIG. 7A is a diagram illustrating an example in which capacitive coupling is formed between an electrode portion and an operator's finger when a touch input is performed in an operation region of the electrostatic-sensing input device according to the embodiment;

FIG. 7B is a diagram illustrating an example in which capacitive coupling is formed between an electrode portion and the operator's finger, between a decorative portion and the operator's finger, and between the decorative portion and the electrode portion when a touch input is performed in an operation region of the electrostatic-sensing input device according to the embodiment;

FIG. 7C is a diagram illustrating an example in which capacitive coupling is formed between the electrode portion and the operator's finger and between the decorative portion and the electrode portion in a case where the decorative portion and the operator's finger come into contact with each other when a touch input is performed in the operation region of the electrostatic-sensing input device according to the embodiment;

FIGS. 8A to 8I are graphs illustrating detection results when touch inputs are performed in the operation regions of the electrostatic-sensing input device according to the embodiment;

FIGS. 9A to 9I are graphs illustrating detection results when touch inputs are performed in operation regions of an electrostatic-sensing input device according to a first modification of the embodiment;

FIGS. 10A to 10I are graphs illustrating detection results when touch inputs are performed in operation regions of an electrostatic-sensing input device according to Comparative Example 1;

FIGS. 11A to 11I are graphs illustrating detection results when touch inputs are performed in operation regions of an electrostatic-sensing input device according to Comparative Example 2;

FIGS. 12A to 12I are graphs illustrating detection results when touch inputs are performed in operation regions of an electrostatic-sensing input device according to Comparative Example 3;

FIG. 13 is a plan view illustrating an input member included in the electrostatic-sensing input device according to the first modification of the embodiment;

FIG. 14 is a plan view illustrating an input member included in an electrostatic-sensing input device according to a second modification of the embodiment;

FIG. 15 is a plan view illustrating an input member included in an electrostatic-sensing input device according to a third modification of the embodiment;

FIG. 16 is a plan view illustrating an input member included in an electrostatic-sensing input device according to a fourth modification of the embodiment;

FIG. 17 is a plan view illustrating an input member included in an electrostatic-sensing input device according to a fifth modification of the embodiment;

FIG. 18 is a plan view illustrating an input member included in an electrostatic-sensing input device according to a sixth modification of the embodiment;

FIG. 19 is a plan view illustrating an input member included in an electrostatic-sensing input device according to a seventh modification of the embodiment;

FIG. 20 is a plan view illustrating an input member included in an electrostatic-sensing input device according to an eighth modification of the embodiment;

FIG. 21 is a plan view illustrating an input member included in an electrostatic-sensing input device according to a ninth modification of the embodiment;

FIG. 22 is a plan view illustrating the electrostatic-sensing input device according to Comparative Example 1;

FIG. 23 is a plan view illustrating the electrostatic-sensing input device according to Comparative Example 2; and

FIG. 24 is a plan view illustrating the electrostatic-sensing input device according to Comparative Example 3.

### DESCRIPTION OF THE PREFERRED EMBODIMENTS

In the technology described in Patent Document 1, it is necessary to connect the first background color layer and the second background color layer to a ground portion via conductive materials such as conductive rubber and a spring such that the first background color layer and the second background color layer function as guard layers. Therefore, in the technology described in Patent Document 1, the number of parts increases, and thus it is difficult to reduce the manufacturing cost.

Further, it has been conventionally known that, in a case where a decorative portion formed of a conductive material and not connected to a ground portion is provided on a touch input surface of an electrostatic-sensing input device, serious disturbance signals are generated, thereby causing problems such as erroneous determinations.

An embodiment of the present disclosure will be described below with reference to the drawings. In the drawings, for the sake of convenience, the Z-axis direction is referred to as an up-down direction, the Y-axis direction is referred to as a left-right direction, and the X-axis direction is referred to as a front-rear direction. Note that the positive Z-axis direction is an upward direction, the positive Y-axis direction is a rightward direction, and the positive X-axis direction is a forward direction.

### Configuration of Electrostatic-Sensing Input Device 100

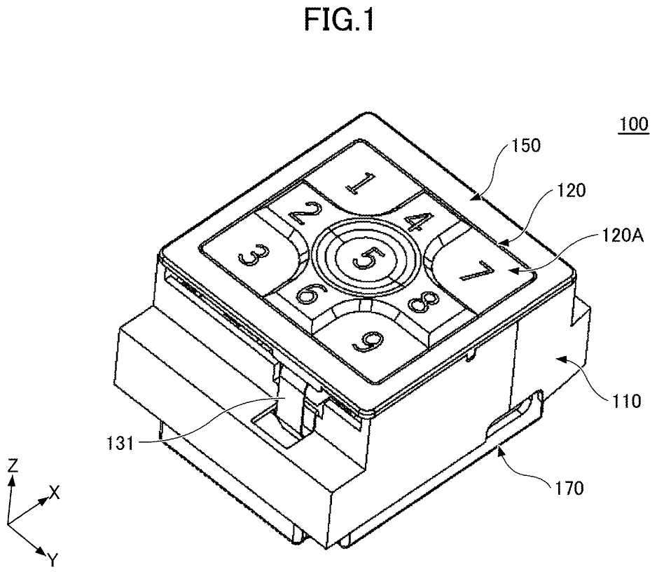

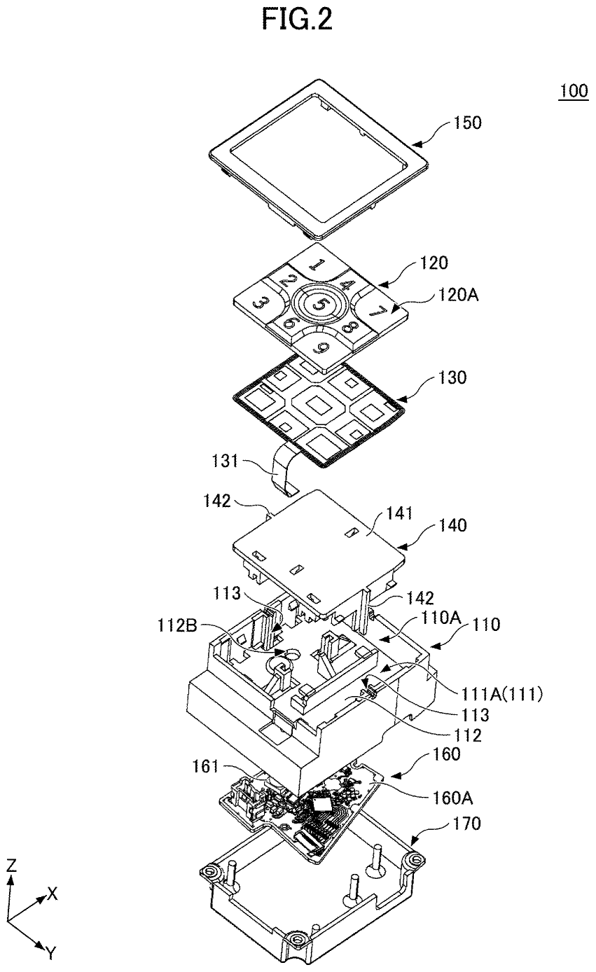

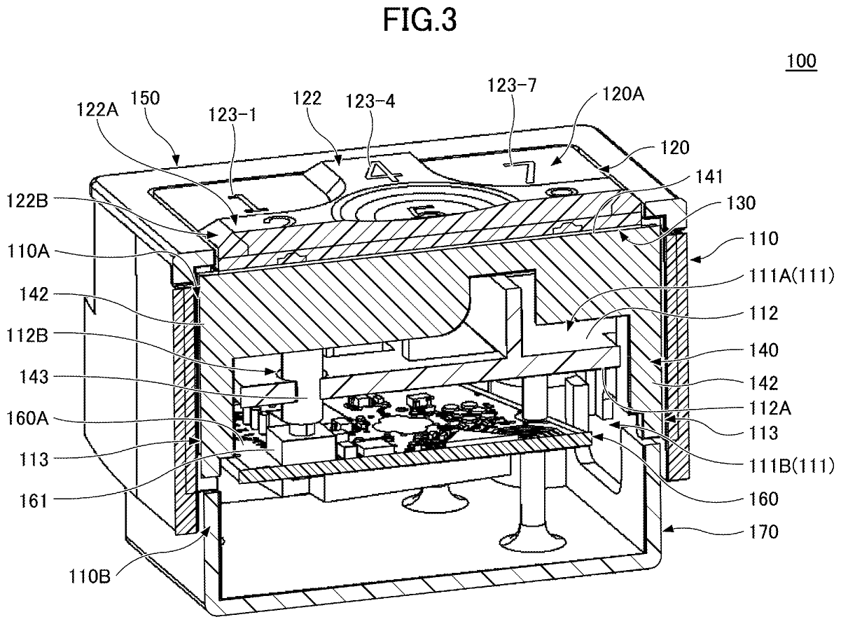

FIG. 1 is a perspective view of the exterior of an electrostatic-sensing input device 100 according to an embodiment. FIG. 2 is an exploded perspective view of the electrostatic-sensing input device 100 according to the embodiment. FIG. 3 is a perspective cross-sectional view illustrating a cross section, take along the YZ plane, of the electrostatic-sensing input device 100 according to the embodiment.

The electrostatic-sensing input device 100 illustrated in FIG. 1 to FIG. 3 is an input device installed in a vehicle such as an automobile and used to electrically control a control target device (for example, an audio device, a navigation device, an air conditioner, a power seat, a power mirror, or the like) installed in the vehicle. However, the electrostatic-sensing input device 100 is not limited thereto, and may be an input device used to control a device (for example, a game console, an aircraft, a railcar, a remote control, or the like) other than the vehicle. The electrostatic-sensing input device 100 has a function for detecting an electrostatic input and a function for detecting a press-input performed on a touch input surface 120A of a knob member 120 (hereinafter referred to as an input member 120).

As illustrated in FIG. 1 to FIG. 3, the electrostatic-sensing input device 100 includes, on the upper surface side of the case 110, the touch input surface 120A configured to receive a touch input by an operator's finger 10 (an example of an “operation body”). The electrostatic-sensing input device 100 includes a sensor sheet 130 provided inside the case 110 and configured to detect the content of the touch input performed on the touch input surface 120A and generate an analog signal. The sensor sheet 130 transmits the analog signal to a substrate 160, and the substrate 160 processes the analog signal and converts it into a digital signal suitable for reception and transmission. The digital signal generates a detection signal indicating the content of the touch input (a touch position, a capacitance value, and the like). The substrate 160 transmits the detection signal, thereby allowing the detection signal to be output to the control target device outside the electrostatic-sensing input device 100.

As illustrated in FIG. 1 to FIG. 3, the electrostatic-sensing input device 100 includes the case 110, the input member 120, the sensor sheet 130, a holder 140, a panel 150, the substrate 160, and a cover 170.

The case 110 is a container-shaped member formed of a resin and having a substantially rectangular parallelepiped shape and a hollow structure. The case 110 has an upper opening 110A having a rectangular shape in a plan view from above (from the positive Z-axis side) at a portion corresponding to the upper surface of the case 110, and a lower opening 110B having a rectangular shape in a plan view from below (from the negative Z-axis side) at a portion corresponding to the lower surface of the case 110.

The case 110 accommodates each component of the electrostatic-sensing input device 100 in an internal space 111. A horizontal flat partition plate 112 is provided at an intermediate position of the internal space 111 of the case 110 in the up-down direction (the Z-axis direction). Thus, the internal space 111 of the case 110 is divided into an upper space 111A on the upper side (the positive Z-axis side) of the partition plate 112 and a lower space 111B on the lower side (the negative Z-axis side) of the partition plate 112.

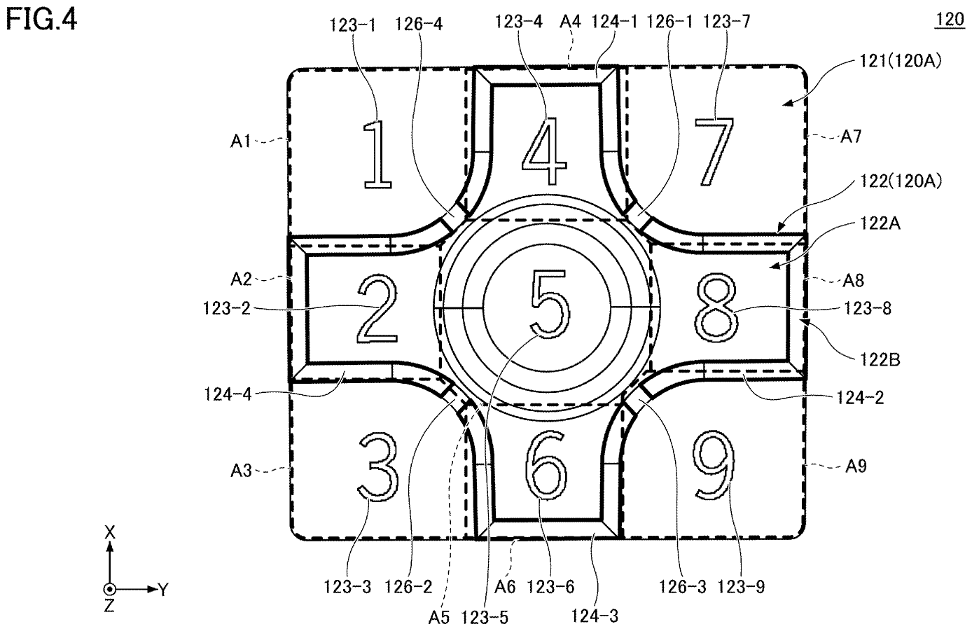

The input member 120 is a substantially flat plate-like member formed of a resin and disposed in the upper opening 110A of the case 110 so as to close the upper opening 110A at the uppermost portion of the electrostatic-sensing input device 100. The input member 120 has an upper surface having a rectangular shape in a plan view from above (from the positive Z-axis side), and the upper surface is the touch input surface 120A configured to receive a touch input by the operator's finger 10. A detailed configuration of the touch input surface 120A will be described later with reference to FIG. 4.

The sensor sheet 130 is a sheet-like member disposed under the input member 120 within the upper opening 110A of the case 110. The sensor sheet 130 has a rectangular shape in a plan view from above (from the positive Z-axis side). The sensor sheet 130 uses an electrostatic detection method to detect a touch input performed by the operator's finger 10 on the touch input surface 120A of the input member 120. The sensor sheet 130 has a strip-shaped connection part 131 extending from the outer edge of the rear side (the negative X-axis side) of the sensor sheet 130. The connection part 131 is connected to the substrate 160. The sensor sheet 130 includes nine electrode portions E1 to E9 (see FIG. 5). The sensor sheet 130 includes wiring portions (not illustrated) that connect the electrode portions E1 to E9 to the substrate 160, and the wiring portions are bundled and arranged in the connection part 131. The sensor sheet 130 outputs a detection signal indicating the content of a detected touch input (a touch position, a capacitance value, and the like) to the substrate 160. A detailed configuration of the sensor sheet 130 will be described later with reference to FIG. 5.

The holder 140 is a block-shaped member formed of a resin and disposed under the sensor sheet 130 within the upper space 111A of the case 110. The holder 140 has a horizontal flat upper surface, and the upper surface serves as a placement surface 141 on which the sensor sheet 130 and the input member 120 are placed. The holder 140 supports the sensor sheet 130 and the input member 120 by having the sensor sheet 130 and the input member 120 placed on the placement surface 141.

The holder 140 is provided in the upper space 111A of the case 110 so as to be movable up and down in the up-down direction (the Z-axis direction). Guide ribs 142 extending linearly in the up-down direction (the Z-axis direction) are provided so as to protrude from side surfaces on the right side (the positive Y-axis side) and the left side (the negative Y-axis side) of the holder 140. The guide ribs 142 are fitted into linear guide grooves 113, which are provided on inner wall surfaces on the right side (the positive Y-axis side) and the left side (the negative Y-axis side) of the case 110 so as to protrude toward the internal space 111 of the case 110, and the guide ribs 142 guide the up-and-down movement of the holder 140 by sliding within the guide grooves 113 in the up-down direction (the Z-axis direction).

The holder 140 has a cylindrical pressing portion 143 extending downward (toward the negative Z-axis side) from a lower surface 140A. The pressing portion 143 extends through a through hole 112B formed in the partition plate 112 of the case 110 to a position above a push switch 161 provided on an upper surface 160A of the substrate 160. When the input member 120 is pressed by the operator's finger 10, the holder 140 moves down together with the input member 120 and the sensor sheet 130, thereby allowing the push switch 161 to be pressed by the pressing portion 143.

The panel 150 is a member formed of a resin, provided on the upper side (the positive Z-axis side) of the case 110 at the same height (position in the Z-axis direction) as the input member 120, and having a rectangular frame shape surrounding the outer periphery of the input member 120. The panel 150 is fixed to the upper end portion of the case 110 by a snap-fit mechanism. The panel 150 decorates the periphery of the input member 120. For this purpose, the surface of the panel 150 is subjected to decorative processing for a metal plating appearance.

The substrate 160 is a flat plate-like member formed of a resin and provided in a horizontal orientation in the lower space 111B of the case 110. For example, a printed wired board (PWB) or the like can be used as the substrate 160. The push switch 161 is provided on the upper surface 160A of the substrate 160 at a position below the pressing portion 143 of the holder 140. When the input member 120 is pressed by the operator's finger 10 and the holder 140 moves down together with the input member 120, the push switch 161 is pressed by the lower surface of the pressing portion 143, and a press detection signal indicating that the input member 120 is pressed is output.

The cover 170 is a saucer-shaped member formed of a resin and attached to the bottom portion of the case 110 so as to close the lower opening 110B of the case 110. The cover 170 is fixed to a lower surface 112A of the partition plate 112 of the case 110 by a plurality of screws (not illustrated).

### Detailed Configuration of Touch Input Surface 120A

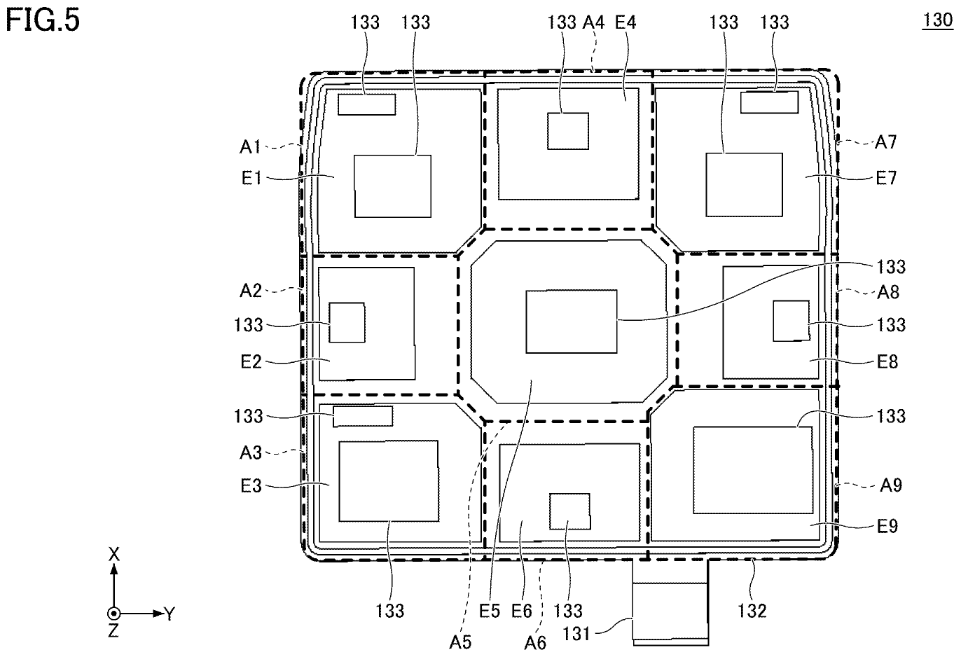

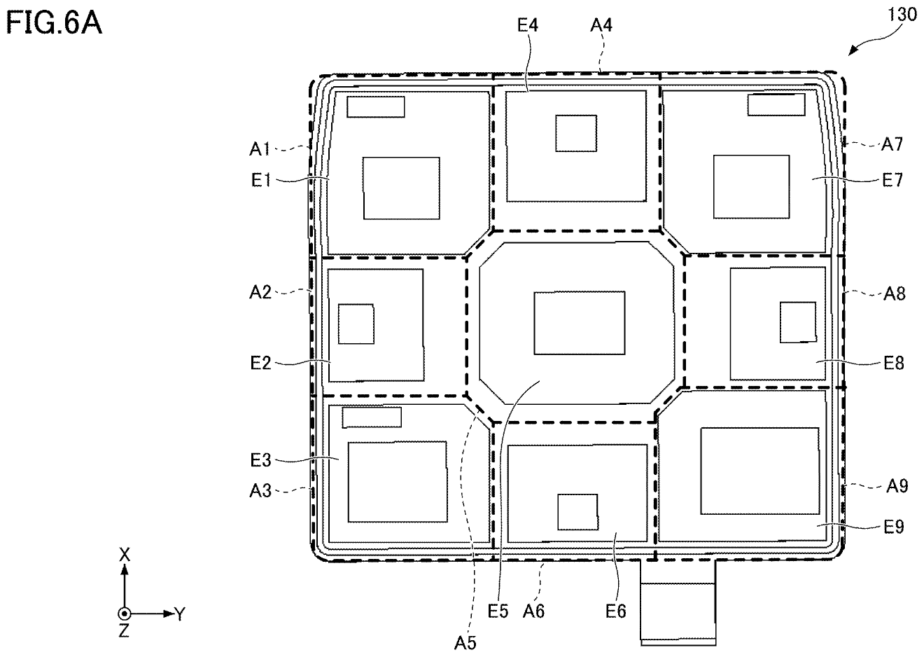

FIG. 4 is a plan view of the input member 120 included in the electrostatic-sensing input device 100 according to the embodiment. FIG. 5 is a plan view of the sensor sheet 130 included in the electrostatic-sensing input device 100 according to the embodiment. FIG. 6A is a diagram illustrating the positional relationship between operation regions A1 to A9 and the electrode portions E1 to E9 of the sensor sheet 130 included in the electrostatic-sensing input device 100 according to the embodiment. FIG. 6B is a diagram illustrating the positional relationship between the operation regions A1 to A9 and decorative portions (124-1 to 124-4) of the input member included in the electrostatic-sensing input device 100 according to the embodiment. In FIG. 4, in order to make the ranges of components included in the input member 120 easy to understand, the outlines of a first decorative portion 124-1, a second decorative portion 124-2, a third decorative portion 124-3, and a fourth decorative portion 124-4 are indicated by thick lines.

As illustrated in FIG. 3 and FIG. 4, the touch input surface 120A of the input member 120 includes a flat base portion 121 that is horizontal (i.e., parallel to the sensor sheet 130) and a substantially cross-shaped bank portion 122 protruding from the base portion 121 in a plan view.

Further, the bank portion 122 includes an upper portion 122A and a side surface portion 122B. The upper portion 122A is a flat portion that is substantially horizontal (i.e., substantially parallel to the sensor sheet 130) and spaced upward (in the positive Z-axis direction) from the base portion 121

The side surface portion 122B is a portion connecting the upper portion 122A and the base portion 121 and having an inclined surface shape that is inclined with respect to the base portion 121.

Further, as illustrated in FIG. 4, the touch input surface 120A of the input member 120 has the nine operation regions A1 to A9. The operation regions A1 to A9 are arranged in a matrix having three rows in the front-rear direction (X-axis direction) and three columns in the left-right direction (Y-axis direction) in a plan view from above (from the positive Z-axis side).

As illustrated in FIG. 4, design portions 123-1 to 123-9 having shapes of characters, graphics, or the like that can be identified by the operator are formed on the touch input surface 120A of the input member 120 so as to overlap the respective nine operation regions A1 to A9. In the present embodiment, as an example, numerals “1” to “9” corresponding to the numbering of the operation regions are displayed at the center of the operation regions A1 to A9. In the following description, these displays are referred to as the design portions 123-1 to 123-9. The input member 120 includes a molded body formed of a light-transmissive white synthetic resin, and an opaque color coating film such as black coating film formed on the surface on the upper side (the positive Z-axis side) of the molded body by coating or the like. The design portions 123-1 to 123-9 are formed by burning a portion of the opaque color coating film using a method such as laser processing to expose the white synthetic resin.

The operation regions A1, A3, A7, and A9 are provided in the base portion 121. Specifically, in a plan view from above (from the positive Z-axis side), the operation region A1 is a region provided at the left front corner of the base portion 121 of the touch input surface 120A. The external dimensions of the operation region A1 are approximately the same as the external dimensions of the electrode portion E1 in a plan view as illustrated in FIG. 5. Specifically, the operation region A1 has slightly larger dimensions than the electrode portion E1, and is set at a position overlapping the electrode portion E1.

As illustrated in FIG. 4, the operation region A3 is a substantially rectangular region provided at the left rear corner of the base portion 121 of the touch input surface 120A. The external dimensions of the operation region A3 are approximately the same as the external dimensions of the electrode portion E3 in a plan view as illustrated in FIG. 5. Specifically, the operation region A3 has slightly larger dimensions than the electrode portion E3, and is set at a position overlapping the electrode portion E3.

The operation regions A7 and A9 are symmetrical to the operation regions A1 and A3 with respect to the X-axis, and have the same relative positional relationship and dimensional relationship with the corresponding electrode portions E7 and E9. Therefore, for the sake of simplicity, a detailed description of the operation regions A7 and A9 will be omitted.

The operation regions A2, A4 to A6, and A8 are provided in the upper portion 122A of the bank portion 122.

As illustrated in FIG. 4, the operation region A5 is a substantially rectangular region provided at the center of the upper portion 122A. Although the operation region A5 is depicted as being surrounded by circles in the design, the operation region A5 has a substantially rectangular shape like the other operation regions. The operation region A5 has approximately the same external dimensions as the electrode portion E5 in a plan view as illustrated in FIG. 5, and is set at a position overlapping the electrode portion E5.

As illustrated in FIG. 4, the operation region A6 is a substantially rectangular region provided in the upper portion 122A and located on the rear side (the negative X-axis side) of the central portion (the operation region A5) and between the operation region A3 and the operation region A9. The external dimensions of the operation region A6 are approximately the same as the external dimensions of the electrode portion E6 in a plan view as illustrated in FIG. 5. Specifically, the operation region A6 has slightly larger dimensions than the electrode portion E6, and is set at a position overlapping the electrode portion E6.

The operation regions A2, A4, A6, and A8 are point-symmetrical with respect to the central portion (the operation region A5) in the up-down and left-right directions, and have the same relative positional relationship and dimensional relationship with the corresponding electrode portions E2, E4, E6, and E8. Therefore, for the sake of simplicity, a detailed description of the operation regions A2, A4, and A8 will be omitted below.

As illustrated in FIG. 4, the touch input surface 120A includes the first decorative portion 124-1, the second decorative portion 124-2, the third decorative portion 124-3, and the fourth decorative portion 124-4 on the side surface portion 122B between the base portion 121 and the upper portion 122A. Further, the side surface portion 122B has a gap 126-1, a gap 126-2, a gap 126-3, and a gap 126-4 between the decorative portions.

The first decorative portion 124-1, the second decorative portion 124-2, the third decorative portion 124-3, and the fourth decorative portion 124-4 are portions on which a thin film formed of a conductive material is formed, and, in the present embodiment, are composed of a metal plating layer. The gap 126-1 is provided between the first decorative portion 124-1 and the second decorative portion 124-2. The gap 126-3 is provided between the second decorative portion 124-2 and the third decorative portion 124-3. The gap 126-2 is provided between the third decorative portion 124-3 and the fourth decorative portion 124-4. The gap 126-4 is provided between the fourth decorative portion 124-4 and the first decorative portion 124-1. In the present embodiment, the metal plating layer forming the decorative portions are not provided in the gap 126-1, the gap 126-2, the gap 126-3, and the gap 126-4. The gap 126-1, the gap 126-2, the gap 126-3, and the gap 126-4 are elements for electrically insulating the first decorative portion 124-1, the second decorative portion 124-2, the third decorative portion 124-3, and the fourth decorative portion 124-4 from each other.

As illustrated in FIG. 4, FIG. 5, FIG. 6A, and FIG. 6B, the first decorative portion 124-1 is provided so as to overlap a portion of the electrode portion E4 of the sensor sheet 130 in a plan view from above (from the positive Z-axis side). The first decorative portion 124-1 is an example of a “first decorative portion”. The electrode portion E4 is an example of a “first electrode portion”. The operation region A4 is an example of a “first operation region”. The first decorative portion 124-1 is disposed at a position overlapping the operation region A4. In the present embodiment, the operation region A4 has a rectangular shape, and the first decorative portion 124-1 is provided along three sides of the outer periphery of the operation region A4. Therefore, the first decorative portion 124-1 has a substantially inverted U-shape in a plan view from above (from the positive Z-axis side).

The second decorative portion 124-2 is disposed so as to overlap a portion of the electrode portion E8 of the sensor sheet 130 in a plan view from above (from the positive Z-axis side). The second decorative portion 124-2 is an example of a “second decorative portion”. The operation region A8 is an example of a “second operation region”. The electrode portion E8 is an example of a “second electrode portion”. The second decorative portion 124-2 is disposed at a position overlapping the operation region A8. In the present embodiment, the operation region A8 has a rectangular shape, and the second decorative portion 124-2 is provided along three sides of the outer periphery of the operation region A8. Therefore, the second decorative portion 124-2 has a substantially inverted C-shape in a plan view from above (from the positive Z-axis side).

The gap 126-1 is provided between the first decorative portions 124-1 and the second decorative portions 124-2. The first decorative portions 124-1 and the second decorative portions 124-2 are insulated by the gap 126-1.

The third decorative portion 124-3 is provided point-symmetrically to the first decorative portion 124-1 with respect to the central portion of the bank portion 122 (with respect to the operation region A5). The third decorative portion 124-3 is an example of a “third decorative portion”.

The fourth decorative portion 124-4 is provided point-symmetrically to the second decorative portion 124-2 with respect to the central portion of the bank portion 122 (with respect to the operation region A5). The fourth decorative portion 124-4 is an example of a “fourth decorative portion”.

The electrode portion E7 is provided point-symmetrically to the electrode portion E3 with respect to the electrode portion E5 provided at the center of the sensor sheet 130. The electrode portion E7 is an example of a “third electrode portion”. The left side (the negative Y-axis side) of the electrode portion E7 and the right side (the positive Y-axis side) of the electrode portion E4 are parallel to and oppose each other. The rear side (the negative X-axis side) of the electrode portion E7 and the front side (the positive X-axis side) of the electrode portion E8 are parallel to and oppose each other.

The gap 126-2 is provided between the third decorative portion 124-3 and the fourth decorative portion 124-4. The third decorative portion 124-3 and the fourth decorative portion 124-4 are insulated by the gap 126-2.

The gap 126-3 is provided between the second decorative portion 124-2 and the third decorative portion 124-3. The second decorative portion 124-2 and the third decorative portion 124-3 are insulated by the gap 126-3.

The gap 126-4 is provided between the first decorative portion 124-1 and the fourth decorative portion 124-4. The first decorative portion 124-1 and the fourth decorative portion 124-4 are insulated by the gap 126-4.

An imaginary line connecting the first decorative portion 124-1, the second decorative portion 124-2, the third decorative portion 124-3, and the fourth decorative portion 124-4 has a cross-shaped outline in a plan view from above (from the positive Z-axis side).

### Detailed Configuration of Sensor Sheet 130

The sensor sheet 130 includes, on a base portion 132 having a rectangular shape in a plan view from above (from the positive Z-axis side), the nine electrode portions E1 to E9 arranged in a matrix having three rows in the front-rear direction (the X-axis direction) and three columns in the left-right direction (the Y-axis direction) in a plan view from above (from the positive Z-axis side). The nine electrode portions E1 to E9 are provided corresponding to the nine operation regions A1 to A9 of the input member 120. The base portion 132 has a film-shaped portion formed of a light-transmissive resin material.

Each of the nine electrode portions E1 to E9 is formed of a conductive material and has a thin film shape. Further, each of the nine electrode portions E1 to E9 has a substantially rectangular shape in a plan view from above (from the positive Z-axis side). Further, each of the nine electrode portions E1 to E9 overlaps a corresponding one of the nine operation regions A1 to A9 of the input member 120 in a plan view from above (from the positive Z-axis side).

Each of the nine electrode portions E1 to E9 can generate a detection signal of a touch input by being capacitively coupled to the operator's finger 10 when the touch input is performed on a corresponding one of the nine operation regions by the operator's finger 10. Then, each of the nine electrode portions E1 to E9 can output the generated detection signal to the substrate 160 via the connection part 131.

The sensor sheet 130 has, in each of the nine electrode portions E1 to E9, a light-transmissive portion 133 formed by being partially opened. Thus, for example, in a configuration in which the electrostatic-sensing input device 100 according to the embodiment includes a light source (for example, an LED or the like) disposed on the upper surface 160A of the substrate 160, light emitted from the light source can pass through each of a plurality of light-transmissive portions 133, and the light that has passed through each of a plurality of light-transmissive portions 133 can illuminate each of the nine operation regions A1 to A9 of the touch input surface 120A of the input member 120. Each of the light-transmissive portions 133 is provided near the center of a corresponding one of the electrode portions E1 to E9. Note that the light-transmissive portions 133 are not necessarily required to achieve the object of the present application and thus may be omitted.

### Positional Relationship between Decorative Portions and Electrode Portions

The operation region A4 illustrated in FIG. 6A and the operation region A4 illustrated in FIG. 6B have the same dimensions and are located at the same position. As illustrated in FIG. 6A and FIG. 6B, the operation region A4 overlaps the electrode portion E4 in a plan view from above (from the positive Z-axis side). Further, the operation region A4 overlaps the first decorative portion 124-1. Further, the operation region A8 overlaps the electrode portion E8. Further, the operation region A8 overlaps the second decorative portion 124-2. Further, the operation region A7 overlaps the electrode portion E7.

The first decorative portion 124-1 is formed so as to overlap the operation region A4 in a plan view from above (from the positive Z-axis side). In the present embodiment, it is sufficient that the first decorative portion 124-1 mostly overlaps the operation region A4 in a plan view from above (from the positive Z-axis side), and the first decorative portion 124-1 may have a shape that slightly extends beyond the electrode portion E4. In the present embodiment, the first decorative portion 124-1 and the second decorative portion 124-2 are provided as a combination of line-shaped conductive patterns having a uniform width of 2 millimeters (mm) (“an example of a predetermined width”). However, the first decorative portion 124-1 may be a conductive pattern that is easily visible, has a decorative appearance, is electrically insulated from other components, and is generally line-shaped as a whole when viewed from above, and the line width of the conductive pattern is not necessarily constant. The first decorative portion 124-1 and the second decorative portion 124-2 may be narrower or wider than 2 mm, and may have a width dimension that varies at any position or may be partially or entirely curved. For example, the first decorative portion 124-1 and the second decorative portion 124-2 may have a bellows shape, an arabesque pattern, or a vine shape.

In the electrostatic-sensing input device 100 according to the embodiment, when a touch input is performed in the operation region A4, capacitive coupling is formed between the operator's finger 10 and the electrode portion E4. At the same time, capacitive coupling is formed between the operator's finger 10 and the first decorative portion 124-1. Further, at the same time, capacitive coupling is formed between the first decorative portion 124-1 and the electrode portion E4.

Further, the second decorative portion 124-2 of the input member 120 overlaps the electrode portion E8 in a plan view from above (from the positive Z-axis side). In a plan view from above (from the positive Z-axis side), the electrode portion E8 disposed at a position overlapping the operation region A8 and the second decorative portion 124-2 disposed at a position overlapping the operation region A8 overlap and are located at the same position.

Thus, in the electrostatic-sensing input device 100 according to the embodiment, when a touch input is performed in the operation region A8, capacitive coupling is formed between the operator's finger 10 and the electrode portion E8. At the same time, capacitive coupling is formed between the operator's finger 10 and the second decorative portion 124-2. Further, at the same time, capacitive coupling is formed between the second decorative portion 124-2 and the electrode portion E8.

In the electrostatic-sensing input device 100 according to the embodiment, the first decorative portion 124-1 and the second decorative portion 124-2 are not electrically connected to another component such as a ground connection. That is, the first decorative portion 124-1 and the second decorative portion 124-2 are electrically independent. In other words, the potentials of the first decorative portion 124-1 and the second decorative portion 124-2 are floating. In still other words, the nodes of the first decorative portion 124-1 and the second decorative portion 124-2 are floating.

In the electrostatic-sensing input device 100 according to the embodiment, the side surface portion 122B of the input member 120 on which the first decorative portion 124-1 and the second decorative portion 124-2 are provided has an inclined surface shape that is inclined with respect to the base portion 121 of the input member 120.

As a result, the electrostatic-sensing input device 100 according to the embodiment can reduce the projected areas of the first decorative portion 124-1 and the second decorative portion 124-2 in a plan view from above (from the positive Z-axis side) as compared to when the side surface portion 122B has a flat shape parallel to the base portion 121. With this configuration, as compared to the substantial area of the first decorative portion 124-1, the electrical influence caused by the first decorative portion 124-1 when a touch input is performed in the operation region A4 can be relatively reduced. Consequently, even if a dimensional mismatch occurs between the first decorative portion 124-1 and the electrode portion E4 due to, for example, manufacturing reasons, disturbance components caused by such mismatch can be minimized. This reduces the need to be concerned about potential disadvantages regarding manufacturing and management costs inherent in the electrostatic-sensing input device 100 according to the embodiment. Therefore, by providing the side surface portion 122B in a direction inclined with respect to the base portion 121, the decorative appearance of the input member 120 can be improved without concerns about an increase in manufacturing and management costs. Note that if the first decorative portion 124-1 and the electrode portion E4 are formed as designed, there is no possibility that such disturbance components occur. The second decorative portion 124-2 has the same functionality as the first decorative portion 124-1.

In the electrostatic-sensing input device 100 according to the embodiment, the side surface portion 122B is provided in a direction inclined with respect to the base portion 121, but the side surface portion 122B may have a perpendicular surface shape that is perpendicular to the base portion 121.

Thus, the electrostatic-sensing input device 100 according to the embodiment can make the projected areas of the first decorating portion 124-1 and the second decorating portion 124-2 zero in a plan view from above (from the positive Z-axis side). That is, the electrostatic-sensing input device 100 according to the embodiment can make the capacitive coupling between the first decorating portion 124-1 and the electrode portion E4 close to zero. Further, the capacitive coupling between the second decorating portion 124-2 and the electrode portion E8 can be made close to zero. Therefore, the electrostatic-sensing input device 100 according to the embodiment eliminates the need to consider disturbance components that could be generated by the first decorative portion 124-1 and the second decorative portion 124-2.

The third decorative portion 124-3 is provided so as to overlap a portion of the electrode portion E6 in a plan view from above (from the positive Z-axis side).

In particular, the third decorative portion 124-3 is formed so as to overlap the operation region A6 in a plan view from above (from the positive Z-axis side).

Thus, in the electrostatic-sensing input device 100 according to the embodiment, when a touch input is performed in the operation region A6 corresponding to the electrode portion E6, capacitive coupling is formed between the operator's finger 10 and the third decorative portion 124-3. At the same time, capacitive coupling is formed between the third decorative portion 124-3 and the electrode portion E6. That is, as compared to when the third decorative portion 124-3 is not provided, the number of paths through which capacitive coupling is formed increases, thereby improving the detection sensitivity of a touch input by the electrode portion E6.

Further, the fourth decorative portion 124-4 of the input member 120 overlaps the operation region A2 in a plan view from above (from the positive Z-axis side).

Thus, in the electrostatic-sensing input device 100 according to the embodiment, when a touch input is performed in the operation region A2 corresponding to the electrode portion E2, capacitive coupling is formed between the operator's finger 10 and the fourth decorative portion 124-4. At the same time, capacitive coupling is formed between the fourth decorative portion 124-4 and the electrode portion E2. That is, as compared to when the fourth decorative portion 124-4 is not provided, the number of paths through which capacitive coupling is formed increases, thereby improving the detection sensitivity of a touch input by the electrode portion E2.

In the electrostatic-sensing input device 100 according to the embodiment, the third decorative portion 124-3 and the fourth decorative portion 124-4 are not electrically connected to another component such as a ground connection. That is, the third decorative portion 124-3 and the fourth decorative portion 124-4 are electrically independent. In other words, the potentials of the third decorative portion 124-3 and the fourth decorative portion 124-4 are floating. In still other words, the nodes of the third decorative portion 124-3 and the fourth decorative portion 124-4 are floating.

Further, in the electrostatic-sensing input device 100 according to the embodiment, the side surface portion 122B of the input member 120 on which the third decorative portion 124-3 and the fourth decorative portion 124-4 are provided has an inclined surface shape that is inclined with respect to the base portion 121 of the input member 120.

### Example of Capacitive Coupling

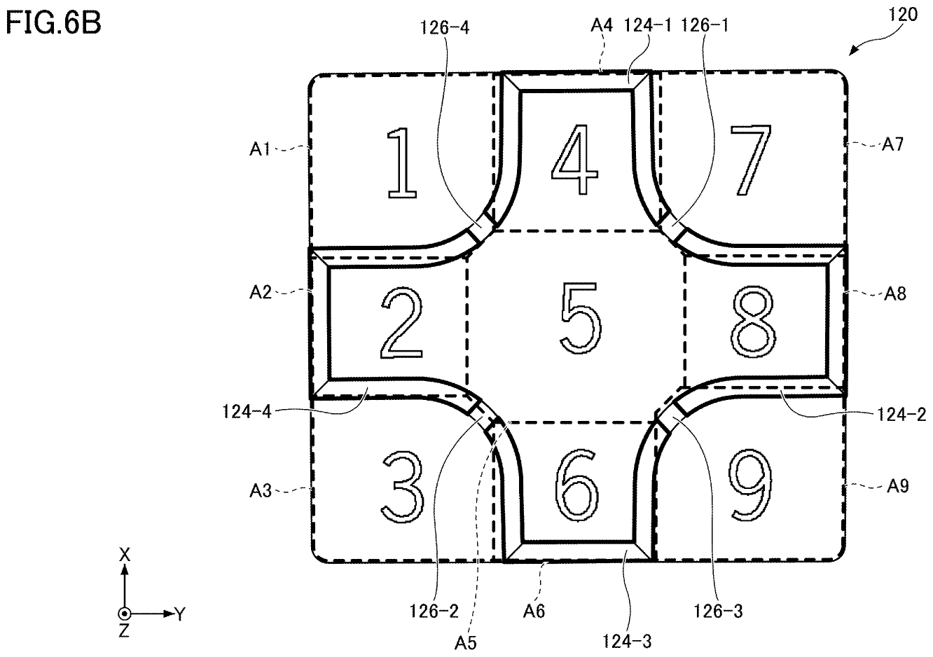

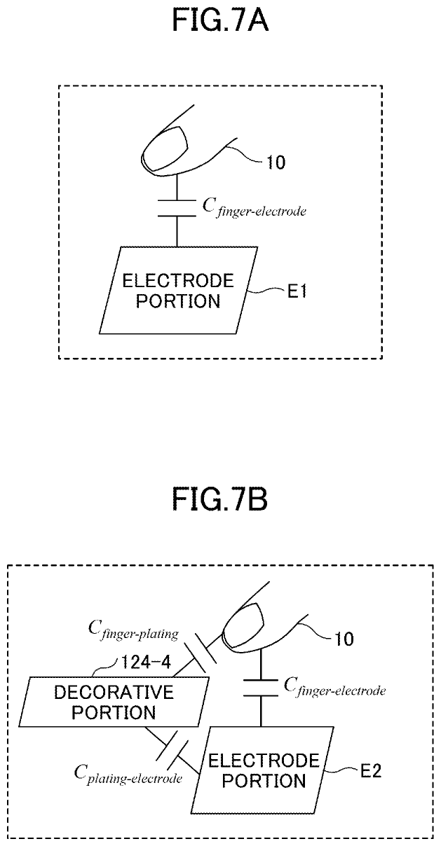

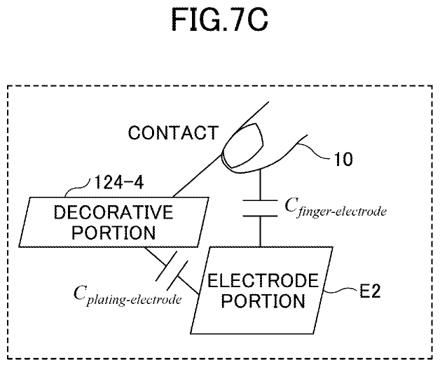

FIG. 7A is a diagram illustrating an example in which capacitive coupling is formed between the electrode portion E1 and the operator's finger 10 when a touch input is performed in the operation region A1 of the electrostatic-sensing input device 100 according to the embodiment. FIG. 7B is a diagram illustrating an example in which capacitive coupling is formed between the electrode portion E2 and the operator's finger 10, between the decorative portion 124-4 and the operator's finger 10, and between the decorative portion 124-4 and the electrode portion E2 when a touch input is performed in the operation region A2 of the electrostatic-sensing input device 100 according to the embodiment. FIG. 7C is a diagram illustrating an example in which capacitive coupling is formed between the electrode portion E2 and the operator's finger 10 and between the decorative portion 124-4 and the electrode portion E2 in a case where the decorative portion 124-4 and the operator's finger 10 come into contact with each other when a touch input is performed in the operation region A2 of the electrostatic-sensing input device 100 according to the embodiment.

As illustrated in FIG. 7A, when a touch input is performed in the operation region A1 where the influence of the decorative portion is small, capacitive coupling is formed between the electrode portion E1 and the operator's finger 10. Note that although FIG. 7A illustrates an example in which a touch input is performed in the operation region A1 for the sake of convenience, capacitive coupling is similarly formed when a touch input is performed in the operation region A3, A7, or A9.

As illustrated in FIG. 7B, when a touch input is performed in the operation region A2, which is close to the decorative portion 124-4 and is greatly influenced by the decorative portion 124-4, in addition to capacitive coupling between the electrode portion E2 and the operator's finger 10, capacitive coupling via the decorative portion 124-4 is also formed. That is, capacitive coupling is also formed between the decorative portion 124-4 and the operator's finger 10 and between the decorative portion 124-4 and the electrode portion E2.

As illustrated in FIG. 7C, in a case where the decorative portion 124-4 and the finger 10 come into contact with each other when a touch input is performed, capacitive coupling is formed between the electrode portion E2 and the operator's finger 10, and capacitive coupling is also formed between the decorative portion 124-4 and the electrode portion E2.

Note that FIG. 7B and FIG. 7C illustrate an example in which a touch input is performed in the operation region A2 for the sake of convenience, capacitive coupling is similarly formed when a touch input is performed in the operation region A4, A6, or A8.

### Theoretical Equation for Coupling Capacitance of Capacitive Coupling

Capacitive coupling involving a decorative portion and its coupling capacitance will be described. Hereinafter, using the symbols indicated in FIG. 7B and FIG. 7C, the coupling capacitance of the capacitive coupling formed between the electrode portion E2 and the operator's finger 10 is denoted as C_{finger-electrode}, and the coupling capacitance of the capacitive coupling formed between the decorative portion 124-4 and the operator's finger 10 is denoted as C_{finger-plating}. Further, the coupling capacitance of the capacitive coupling formed between the decorative portion 124-4 and the electrode portion E2 is denoted as C_{plating-electrode}. Note that the magnitude of C_{plating-electrode} varies depending on the shape and the arrangement of the decorative portion 124-4.

In the situation illustrated in FIG. 7B, the coupling capacitance (C) of the capacitive coupling formed between the finger 10 and the electrode portion E2 is determined by Equation (1) below.

$$C = ( ( {C}_{finger - plating} \times {C}_{plating - electrode} ) / ( {C}_{finger - plating} + {C}_{plating - electrode} ) ) + {C}_{finger - electrode} \qquad ( 1 )$$

According to Equation (1), in a case where an electrostatic detection part includes a decorative portion, it can be said that the magnitude (C) of capacitive coupling is necessarily greater than C_{finger-electrode}.

### Graphs Illustrating Differential Capacitance Detection Values of Capacitance Detection Circuits

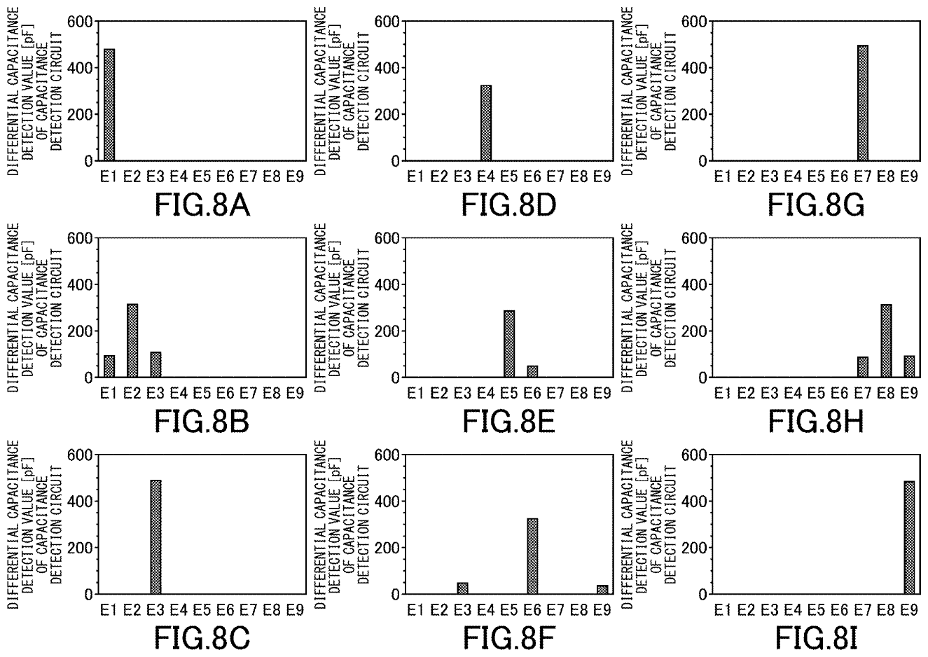

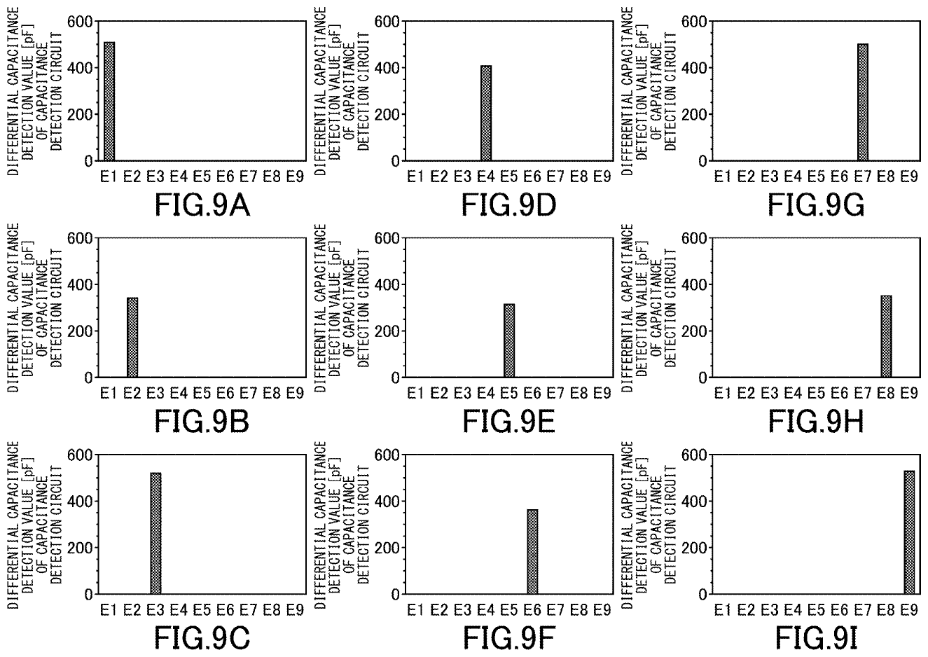

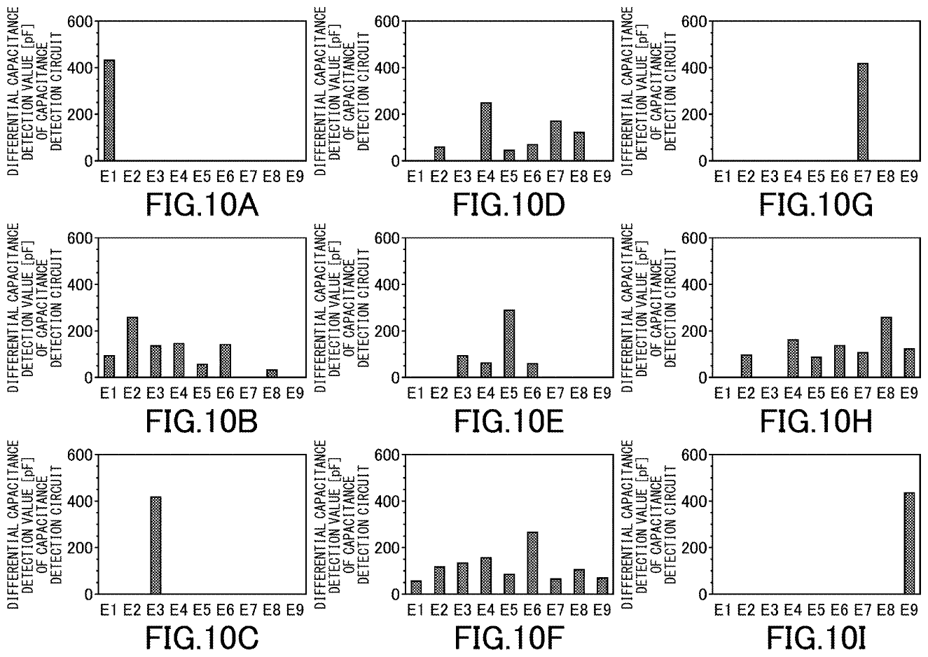

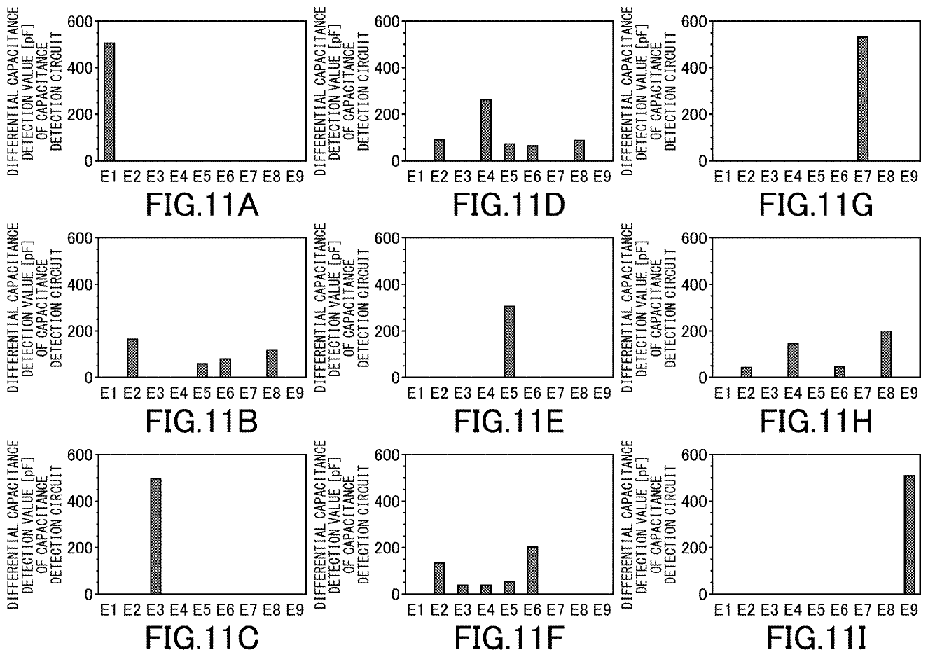

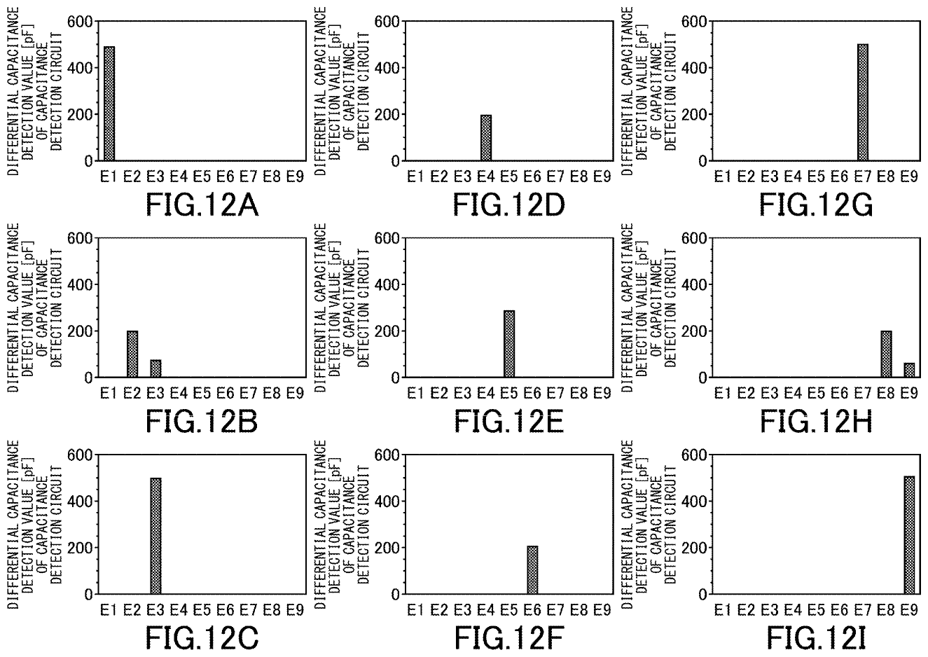

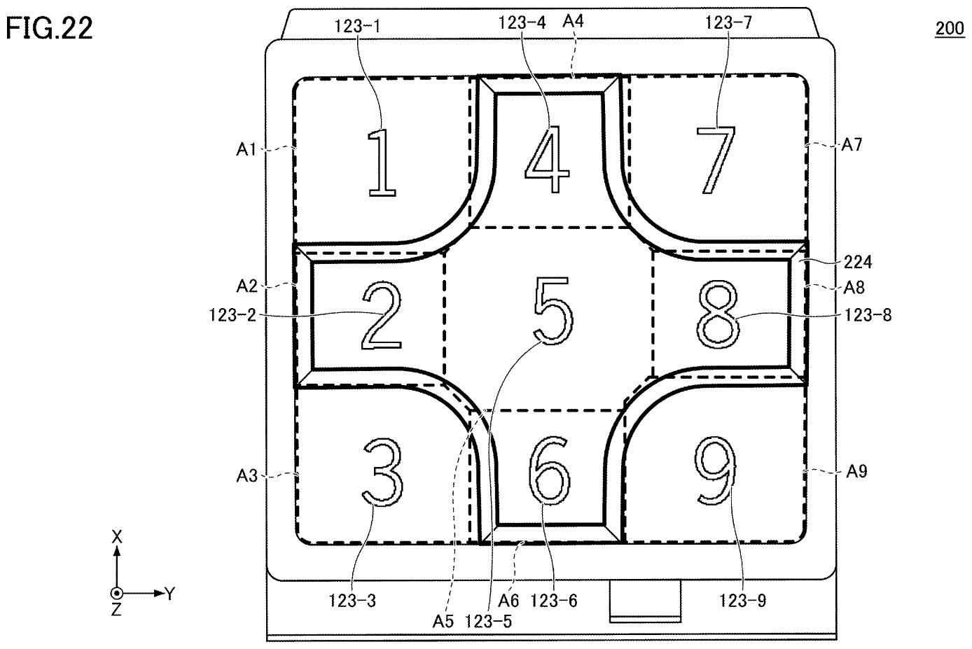

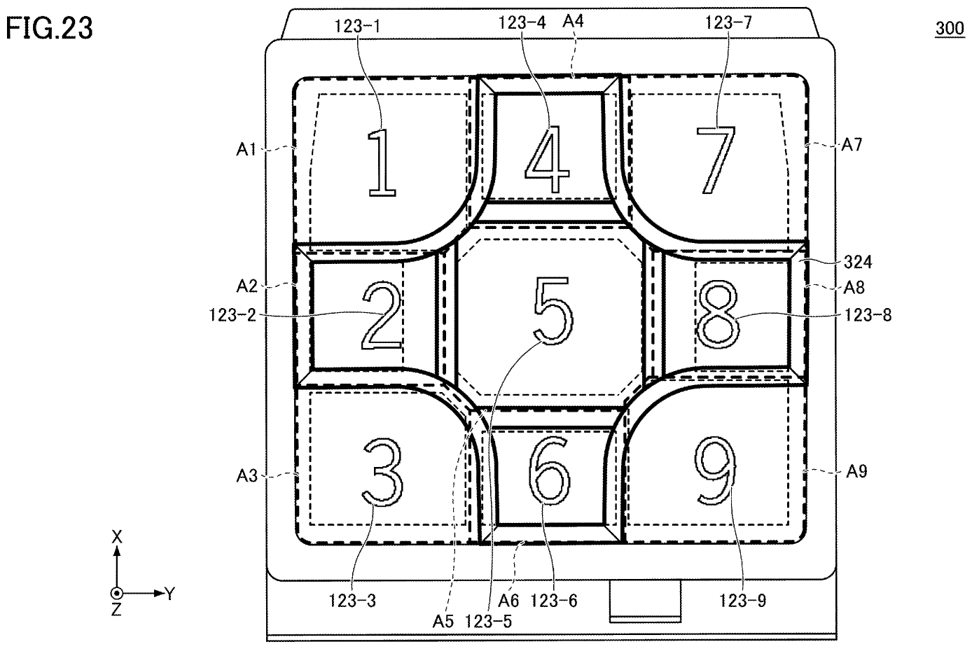

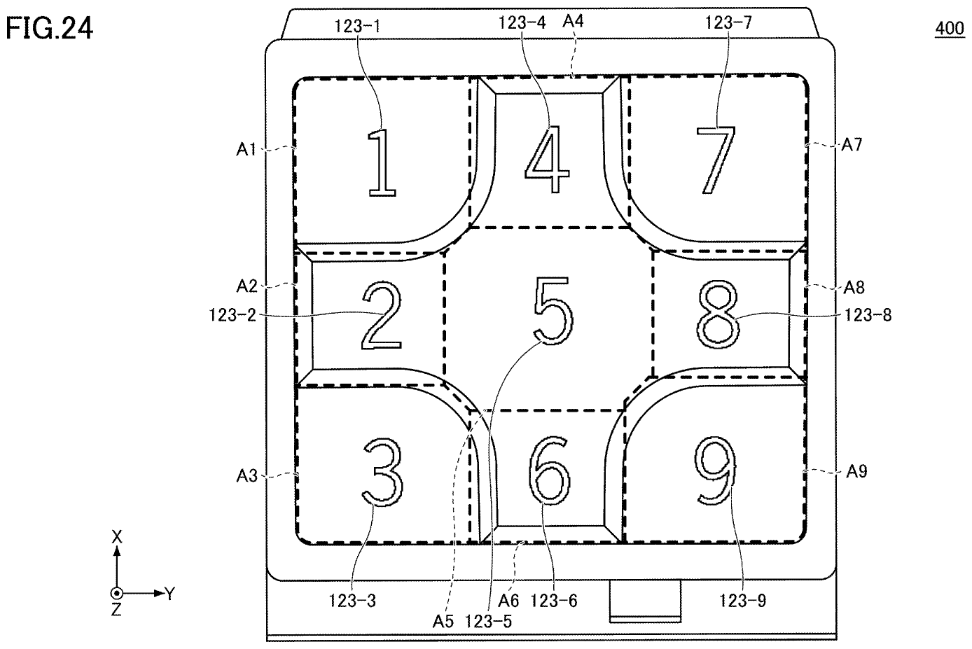

FIGS. 8A to 8I are graphs illustrating detection results when touch inputs are performed in the operation regions A1 to A9 of the electrostatic-sensing input device 100 according to the embodiment. FIGS. 9A to 9I are graphs illustrating detection results when touch inputs are performed in operation regions A1 to A9 of an electrostatic-sensing input device 100 according to a first modification of the embodiment. FIGS. 10A to 10I are graphs illustrating detection results when touch inputs are performed in operation regions A1 to A9 of an electrostatic-sensing input device 200 according to Comparative Example 1 illustrated in FIG. 22. FIGS. 11A to 11I are graphs illustrating detection results when touch inputs are performed in operation regions A1 to A9 of an electrostatic-sensing input device 300 according to Comparative Example 2 illustrated in FIG. 23. FIGS. 12A to 12I are graphs illustrating detection results when touch inputs are performed in operation regions A1 to A9 of an electrostatic-sensing input device 400 according to Comparative Example 3 illustrated in FIG. 24.

FIGS. 8A to 8I are nine graphs illustrating the results of input operations performed in the respective nine operation regions A1 to A9. FIG. 8A to FIG. 8I are arranged in a 3×3 matrix in accordance with the positions of the nine operation regions A1 to A9 of the touch input surface 120A where the input operations are performed. FIGS. 9A to 9I, FIGS. 10A to 10I, FIGS. 11A to 11I, and FIGS. 12A to 12I are displayed in the same manner as FIGS. 8A to 8I, respectively.

Further, FIGS. 8A to 8I indicate detection values of nine electrode portions E1 to E9 when touch inputs are performed in the respective operation regions. The same applies to FIGS. 9A to 9I, FIGS. 10A to 10I, FIGS. 11A to 11I, and FIGS. 12A to 12I.

FIG. 8A is a bar graph summarizing evaluation values of detection sensitivity when a touch input is performed in the operation region A1 of the electrostatic-sensing input device 100 according to the embodiment. More specifically, the leftmost bar (E1) of nine bars constituting FIG. 8A is a bar indicating an evaluation value (480 [pF]) calculated based on a value detected from the electrode portion E1 when the touch input is performed in the operation region A1 of the electrostatic-sensing input device 100 according to the embodiment. This evaluation value is a differential value between a capacitance value detected from the electrode portion E1 when the finger 10 and the operation region A1 of the input member 120 are sufficiently separated from each other in a non-contact state and a capacitance value detected from the electrode portion E1 when the finger 10 is in contact with the operation region A1 of the input member 120. Note that this evaluation was performed by performing analog-to-digital (A/D) conversion on the capacitance values actually detected from the electrode portion E1, recording the converted values, and then substituting the recorded values into a function for calculation. A similar evaluation was performed for each of the electrode portions E2 to E9, and the results of the evaluations for the electrode portions E1 to E9 are summarized in FIG. 8A.

In general, a capacitance value after A/D conversion does not have a unit. Therefore, a recorded value obtained by A/D-converting a capacitance value detected from each of the electrode portions E1 to E9 and a differential value thereof is, strictly speaking, unitless. However, because the results are indicated as bars, the unit of the vertical axis in each of FIG. 8A to FIG. 12I is set to “differential capacitance detection value [pF] of capacitance detection circuit” for the sake of convenience.

Further, with respect to cases where touch inputs are performed in the operation regions A2 to A9, evaluations similar to that of FIG. 8A were performed to produce FIG. 8B to FIG. 8I. Thereafter, the layout was adjusted, and FIG. 8A to FIG. 8I were arranged in accordance with the arrangement of the operation regions A1 to A9, thereby forming a single set of data. According to this configuration, the nine graphs serve as data that allows for visual understanding of which electrode portion among the electrode portions E1 to E9 responds when a touch input is performed in any one of the operation regions A1 to A9. Further, for example, when some of the signals detected from the electrode portions E1 to E9 conflict with each other, the nine graphs serve as data for intuitively understanding the degree of the conflict and the positional information of the electrode portions that have generated the conflicting signals.

FIG. 9A to FIG. 9I illustrate results obtained by performing evaluations similar to those of FIG. 8A to FIG. 8I for the electrostatic-sensing input device 100 according to the first modification, and the results are summarized in the form of bar graphs.

FIG. 10A to FIG. 10I illustrate results obtained by performing evaluations similar to those of FIG. 8A to FIG. 8I for the electrostatic-sensing input device 200 according to Comparative Example 1, and the results are summarized in the form of bar graphs.

FIG. 11A to FIG. 11I illustrate results obtained by performing evaluations similar to those of FIG. 8A to FIG. 8I for the electrostatic-sensing input device 300 according to Comparative Example 2, and the results are summarized in the form of bar graphs.

FIG. 12A to FIG. 12I illustrate results obtained by performing evaluations similar to those of FIG. 8A to FIG. 8I for the electrostatic-sensing input device 400 according to Comparative Example 3, and the results are summarized in the form of bar graphs.

### Characteristics of Comparative Example 1

Comparative Example 1 is an example of an electrostatic-sensing input device in which problems such as erroneous determinations occur. As illustrated in FIG. 22, the electrostatic-sensing input device 200 according to Comparative Example 1 includes a decorative portion 224 having a continuous line shape without gaps. The decorative portion 224 is composed of a plating layer formed of a conductive material and passes through operation regions A2, A4, A6, and A8. The decorative portion 224 is disposed adjacent to operation regions A1, A3, A7, and A9. The electrostatic-sensing input device 200 according to Comparative Example 1 has the same configuration as the electrostatic-sensing input device 100, except that the shape of the decorative portion 224 is different. As illustrated in FIG. 10B, FIG. 10D, FIG. 10F, and FIG. 10H, in the electrostatic-sensing input device 200 according to Comparative Example 1, signals detected from respective electrode portions conflict with each other, and the degree of the conflict is significant. For this reason, erroneous determinations frequently occur, and the electrostatic-sensing input device fails to function properly as an input device. Explaining this problem by taking FIG. 10H as an example, the differential capacitance detection value at an electrode portion E8 corresponding to the operation region A8 in which a touch input is performed is 260 [pF]. A differential capacitance detection value at an electrode portion E2 is 100 [pF], a differential capacitance detection value at an electrode portion E4 is 164 [pF], a differential capacitance detection value at an electrode portion E5 is 88 [pF], and a differential capacitance detection value at an electrode portion E6 is 140 [pF]. Further, a differential capacitance detection value at an electrode portion E7 is 108 [pF], and a differential capacitance detection value at an electrode portion E9 is 124 [pF]. In particular, because the differential capacitance detection value (164 [pF]) at the electrode portion E4 is proportionally close to the differential capacitance detection value (260 [pF]) at the electrode portion E8, it is difficult to determine a touch input position by a determination method based on a threshold value. It is presumed that this problem occurs because capacitive coupling in the form illustrated in FIG. 7C is formed at the electrode portions E2, E4, E5, E6, E7, and E9 due to the inappropriate shape of the decorative portion 224.

### Characteristics of Comparative Example 2

Comparative Example 2 is also an example of an electrostatic-sensing input device in which problems such as erroneous determinations occur. As illustrated in FIG. 23, the electrostatic-sensing input device 300 according to Comparative Example 2 includes a decorative portion 324 without gaps. The electrostatic-sensing input device 300 according to Comparative Example 2 has the same configuration as the electrostatic-sensing input device 100, except that the shape of the decorative portion is different. The decorative portion 324 is composed of a plating layer formed of a conductive material and passes through operation regions A2, A4, A6, and A8. As illustrated in FIG. 11B, FIG. 11D, FIG. 11F, and FIG. 11H, in the electrostatic-sensing input device 300 according to Comparative Example 2, signals detected from respective electrode portions conflict with each other, and the degree of the conflict is significant. For this reason, erroneous determinations frequently occur, and the electrostatic-sensing input device fails to function properly as an input device.

### Characteristics of Comparative Example 3

Comparative Example 3 is an example of an electrostatic-sensing input device without a decorative portion, which is prepared for reference. As illustrated in FIG. 24, the electrostatic-sensing input device 400 according to Comparative Example 3 includes no decorative portion. The electrostatic-sensing input device 400 according to Comparative Example 3 has the same configuration as the electrostatic-sensing input device 100, except that the electrostatic-sensing input device 400 includes no decorative portion. As illustrated in FIG. 12A to FIG. 12I, the electrostatic-sensing input device 400 according to Comparative Example 3 does not have any notable problems as an electrostatic-sensing input device. For example, as illustrated in FIG. 12H, when a touch input is performed in an operation region A8 of the electrostatic-sensing input device 400, a differential capacitance detection value of about 204 [pF] is detected from an electrode portion E8. Because the electrostatic-sensing input device 400 according to Comparative Example 3 includes no decorative portion, the electrostatic-sensing input device 400 according to Comparative Example 3 is inferior in design as compared to the other electrostatic-sensing input devices described herein.

### Characteristics of Electrostatic-Sensing Input Device 100

The detection sensitivity of the electrostatic-sensing input device 100 will be described as an effect of the present disclosure. As illustrated in FIG. 8H, when a touch input is performed in the operation region A8 of the electrostatic-sensing input device 100, a differential capacitance detection value of about 316 [pF] is detected from the electrode portion E8. Further, at the same time, a differential capacitance detection value of about 80 [pF] is detected from the electrode portion E7, and a differential capacitance detection value of about 96 [pF] is detected from the electrode portion E9. However, the magnitudes of signals detected from the electrode portions E7 and E9 are significantly smaller than the magnitude of a signal detected from the electrode portion E8. Therefore, the signals detected from the electrode portions E7 and E9 illustrated in FIG. 8H do not interfere with determining of the position (operation region A8), where the touch input is performed, by a determination method using a threshold value. Further, in FIG. 8A to FIG. 8G and FIG. 8I, no signal conflict that acts as an obstacle to the determination method using the threshold value is observed. This tendency indicates that the decorative portions of the electrostatic-sensing input device 100 do not induce any disturbance component, or that a disturbance component induced by the decorative portions of the electrostatic-sensing input device 100 is very small.

Further, the differential capacitance detection value (316 [pF]) detected from the electrode portion E8 in FIG. 8H is significantly larger than the differential capacitance detection value (204 [pF]) detected from the electrode portion E8 in FIG. 10H. The differential capacitance detection values [pF] of the capacitance detection circuits described herein were all measured under the same conditions. Thus, this difference indicates that the detection sensitivity of the electrostatic-sensing input device 100 is about 50% larger than the detection sensitivity of the electrostatic-sensing input device 400 of Comparative Example 3. Further, similar to the comparison between FIG. 8H and FIG. 10H, in FIG. 8B, FIG. 8D, and FIG. 8F, a tendency that the detection sensitivity is increased as compared to that of the electrostatic-sensing input device 400 of Comparative Example 3 can be observed. This tendency indicates that the touch detection sensitivity of the electrostatic-sensing input device 100 is increased as theoretically confirmed using Equation (1) by providing the decorative portions.

### Characteristics of Electrostatic-Sensing Input Device 100 According to First Modification

As illustrated in FIG. 9H, when a touch input is performed in the operation region A8 of the electrostatic-sensing input device 100 according to the first modification, a differential capacitance detection value of about 352 [pF] is detected from an electrode portion E8. At this time, because no signal is generated from electrode portions other than the electrode portion E8, no conflict occurs.

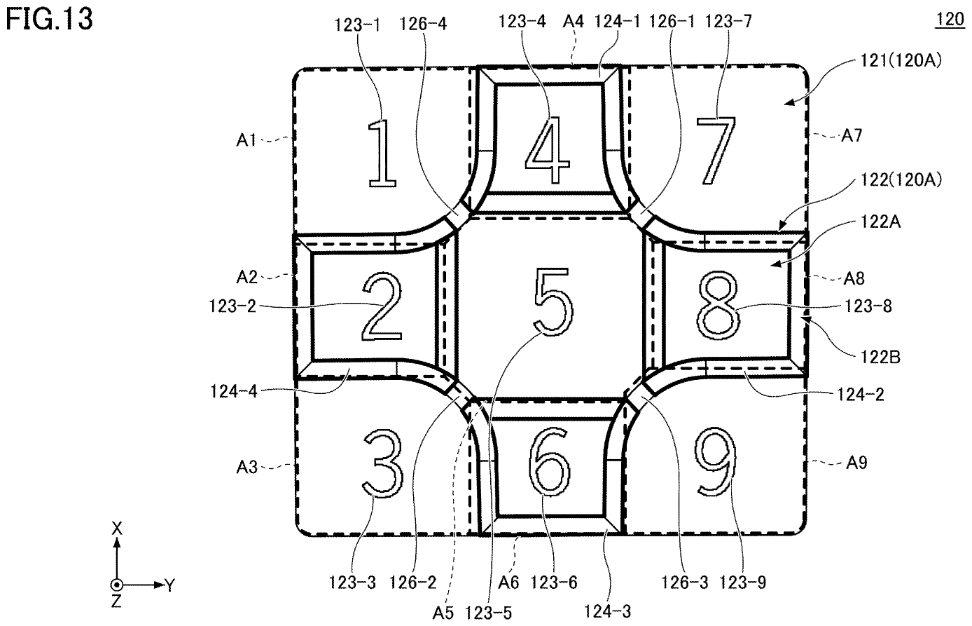

Further, the differential capacitance detection value (352 [pF]) detected from the electrode portion E8 of FIG. 9H is significantly larger than the differential capacitance detection value (204 [pF]) detected from the electrode portion E8 of FIG. 10H. Further, the differential capacitance detection value (352 [pF]) detected from the electrode portion E8 of FIG. 9H is significantly larger than the differential capacitance detection value (316 [pF]) detected from the electrode portion E8 of FIG. 8H. As illustrated in FIG. 13, this characteristic is presumed to be because the entire shape of a second decorative portion 124-2 is a closed-loop shape, thereby resulting in relatively large C_{plating-electrode} in Equation (1).

### Input Members 120 According to First to Third Modifications

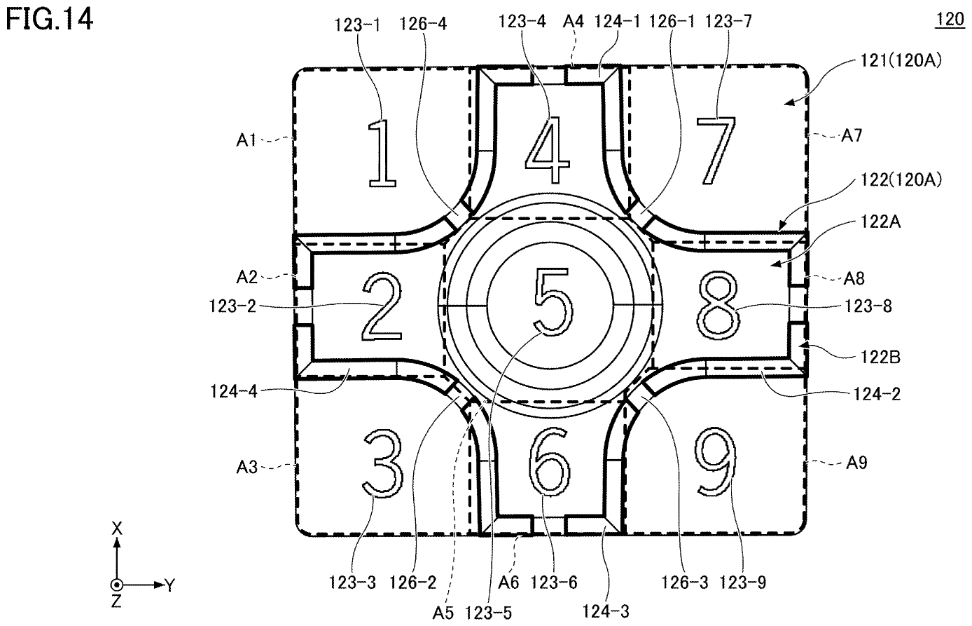

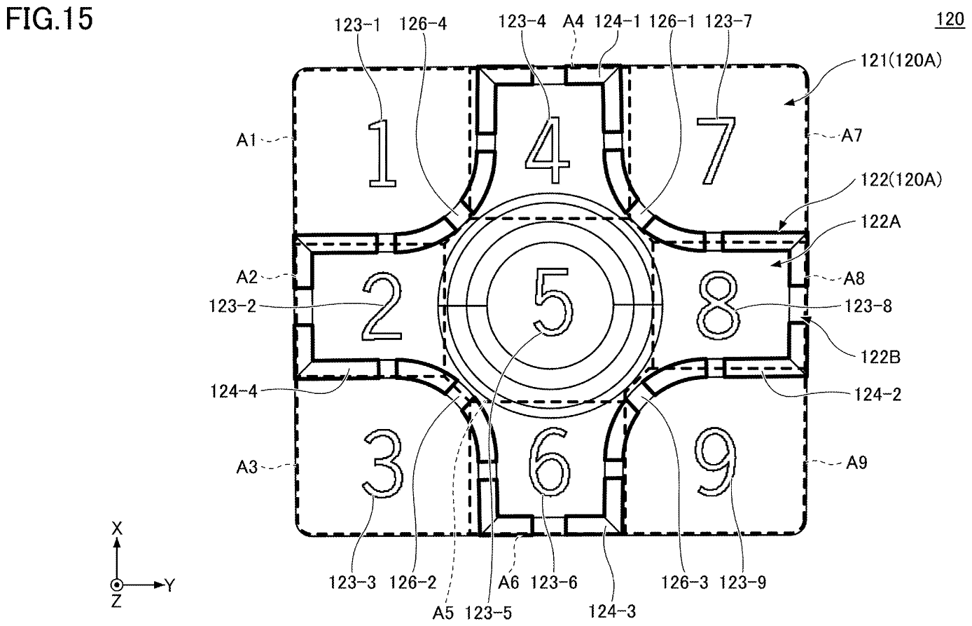

FIG. 13 is a plan view illustrating an input member 120 included in the electrostatic-sensing input device 100 according to the first modification of the embodiment. FIG. 14 is a plan view illustrating an input member 120 included in an electrostatic-sensing input device 100 according to a second modification of the embodiment. FIG. 15 is a plan view illustrating an input member 120 included in an electrostatic-sensing input device 100 according to a third modification of the embodiment.

In FIG. 13 to FIG. 15, the outlines of first decorative portions 124-1, second decorative portions 124-2, third decorative portions 124-3, and fourth decorative portions 124-4 are indicated by thick lines for the sake of convenience.

In the input member 120 illustrated in FIG. 4, each of the first decorative portion 124-1, the second decorative portion 124-2, the third decorative portion 124-3, and the fourth decorative portion 124-4 surround three sides of a corresponding operation region. Further, each of the first decorative portion 124-1, the second decorative portion 124-2, the third decorative portion 124-3, and the fourth decorative portion 124-4 has a shape (is substantially U-shaped) in which a portion, located on the center side of the upper portion 122A (that is, on the operation region A5 side), of each decorative portion is discontinuous.

As illustrated in FIG. 13, in the input member 120 according to the first modification, each of the first decorative portion 124-1, the second decorative portion 124-2, the third decorative portion 124-3, and the fourth decorative portion 124-4 has a shape in which a portion, located on the center side of the upper portion 122A (that is, on the operation region A5 side), of each decorative portion is continuous. That is, the first decorative portion 124-1 has a closed shape (a substantially rectangular shape) that surrounds the four sides of the operation region A4. In other words, the first decorative portion 124-1 is provided in a closed-loop shape. Each of the second decorative portion 124-2, the third decorative portion 124-3, and the fourth decorative portion 124-4 has a shape similar to the shape of the first decorative portion 124-1.

Further, as illustrated in FIG. 14, in the input member 120 according to the second modification, each of the first decorative portion 124-1, the second decorative portion 124-2, the third decorative portion 124-3, and the fourth decorative portion 124-4 is substantially U-shaped as a whole, but has a shape in which a portion of one side of each decorative portion located opposite to the center side of the upper portion 122A (that is, opposite to the operation region A5 side) is discontinuous. In a plan view, an imaginary line connecting the first decorative portion 124-1, the second decorative portion 124-2, the third decorative portion 124-3, and the fourth decorative portion 124-4 according to the second modification has a substantially cross-shaped outline.

Further, As illustrated in FIG. 15, in the input member 120 according to the third modification, each of the first decorative portion 124-1, the second decorative portion 124-2, the third decorative portion 124-3, and the fourth decorative portion 124-4 is substantially U-shaped as a whole, but has a shape in which a portion of each of its three sides surrounding three sides of a corresponding operation region is discontinuous. In a plan view, an imaginary line connecting the first decorative portion 124-1, the second decorative portion 124-2, the third decorative portion 124-3, and the fourth decorative portion 124-4 according to the third modification has a substantially cross-shaped outline.

Note that the shape of each of the first decorative portion 124-1, the second decorative portion 124-2, the third decorative portion 124-3, and the fourth decorative portion 124-4 is not limited to being substantially U-shaped, and may be substantially V-shaped or substantially C-shaped in a plan view from above.

### Input Member 120 According to Fourth Modification

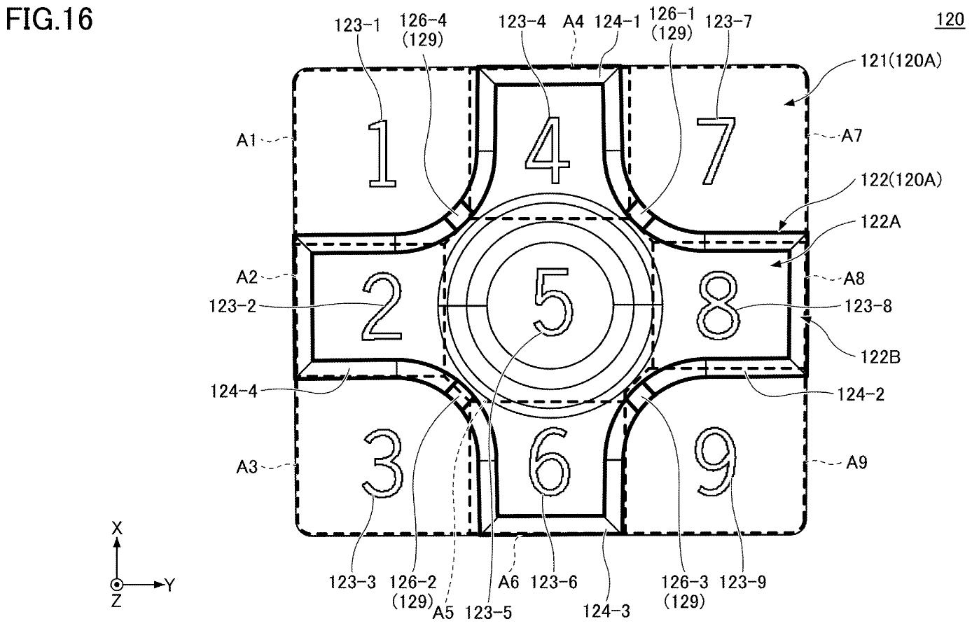

FIG. 16 is a plan view illustrating an input member 120 included in an electrostatic-sensing input device 100 according to a fourth modification of the embodiment.

Note that, in FIG. 16, the outlines of a first decorative portion 124-1, a second decorative portion 124-2, a third decorative portion 124-3, a fourth decorative portion 124-4, and insulating members 129 are indicated by thick lines for the sake of convenience.

As illustrated in FIG. 16, in the input member 120 according to the fourth modification, an insulating member 129 formed of an insulating material is provided between two adjacent decorative portions and thus the two adjacent decorative portions are insulated by the insulating member 129. Insulating members 129 are formed in respective gaps 126-1, 126-2, 126-3, and 126-4. The insulating members 129 preferably have a color tone close to that of a material forming the first decorative portion 124-1, the second decorative portion 124-2, the third decorative portion 124-3, and the fourth decorative portion 124-4.

Thus, in the input member 120 according to the fourth modification, two adjacent decorative portions are electrically separated from each other, but the two adjacent decorative portions are formed continuously in terms of design, and can have a substantially cross-shaped outline. Therefore, the input member 120 according to the fourth modification can be visually excellent as compared to the input member 120 illustrated in FIG. 4.

### Input Members 120 According to Fifth to Ninth Modifications

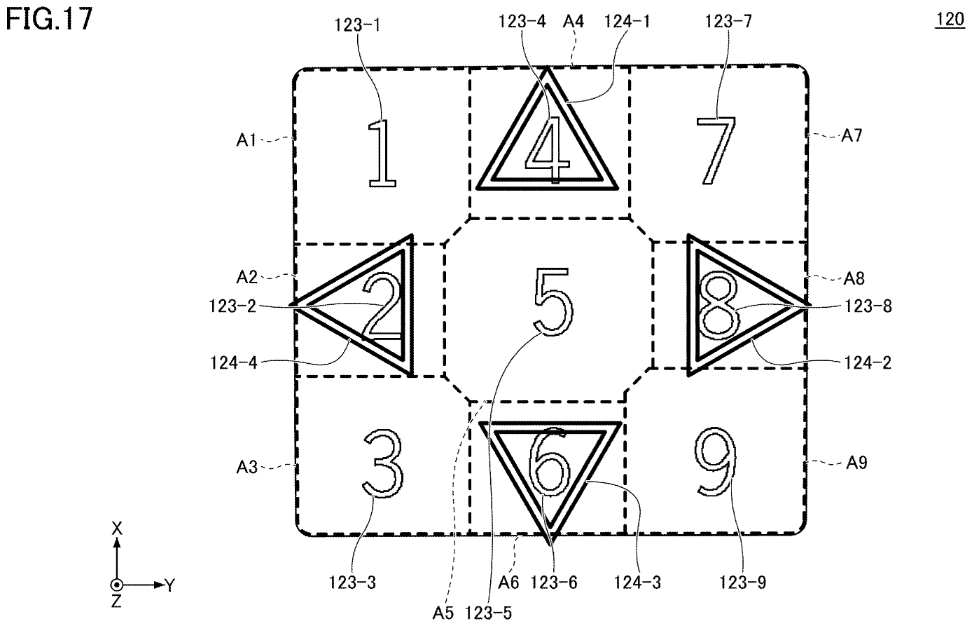

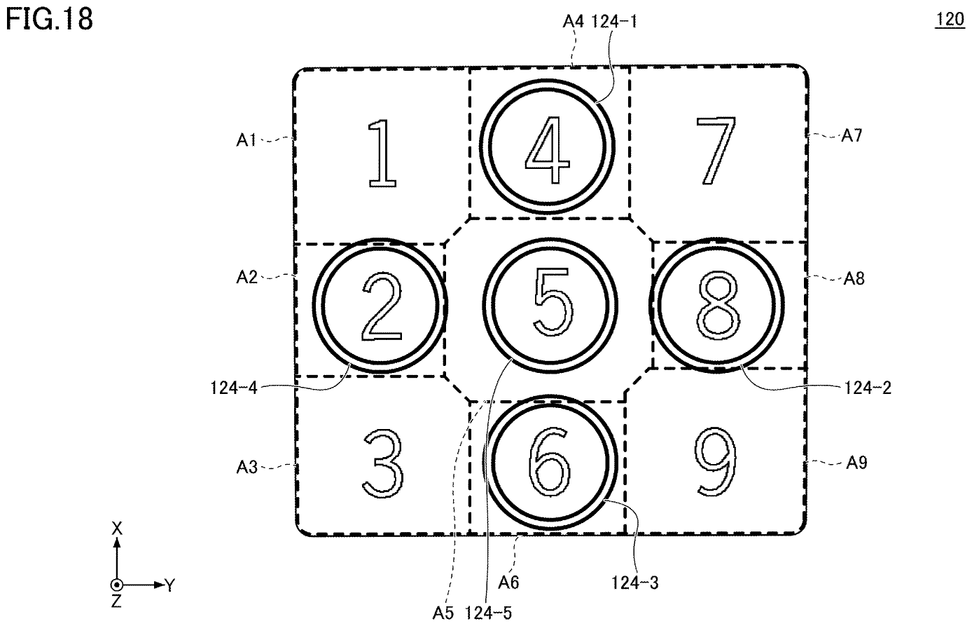

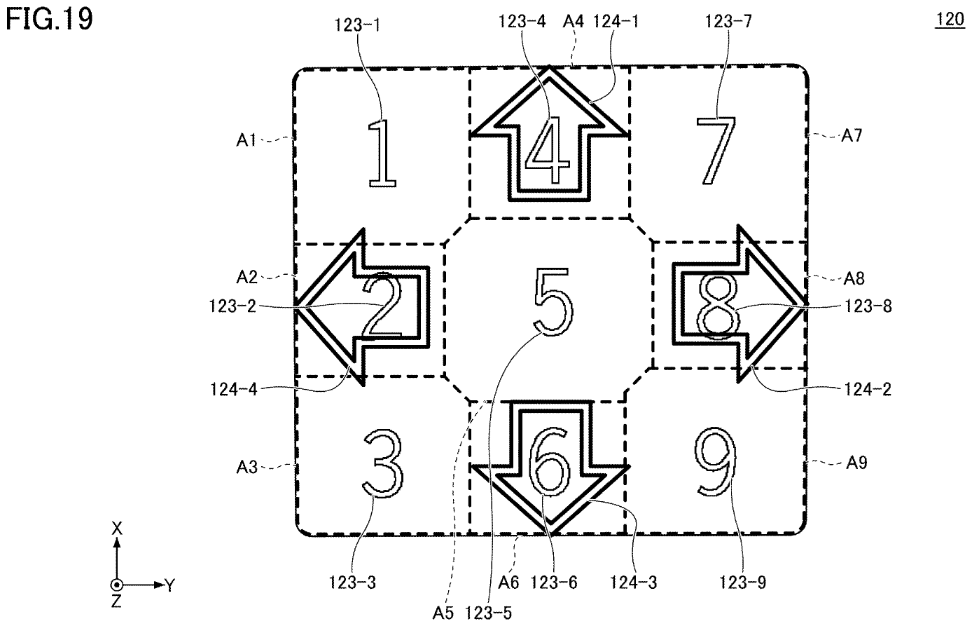

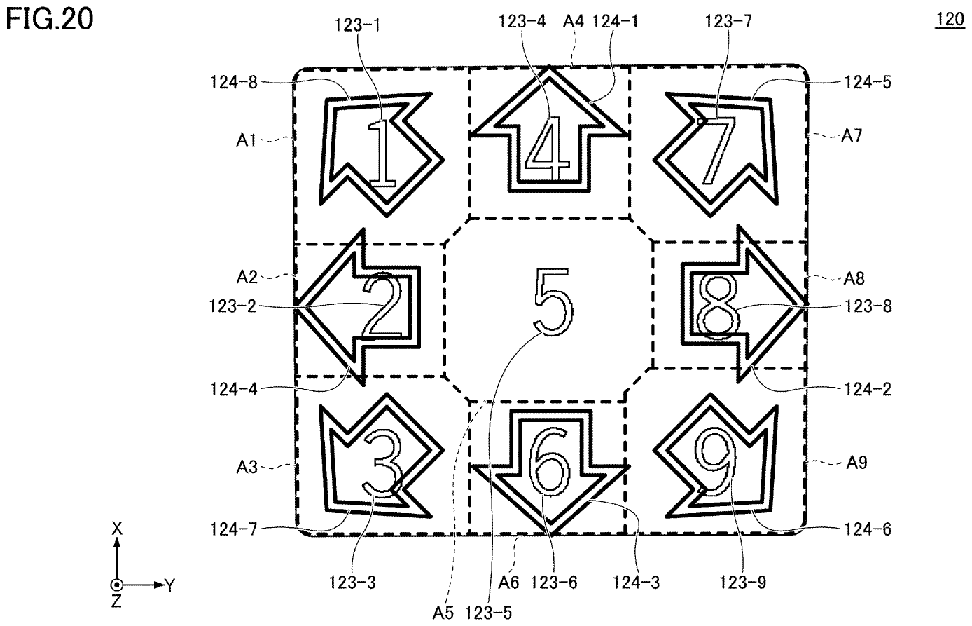

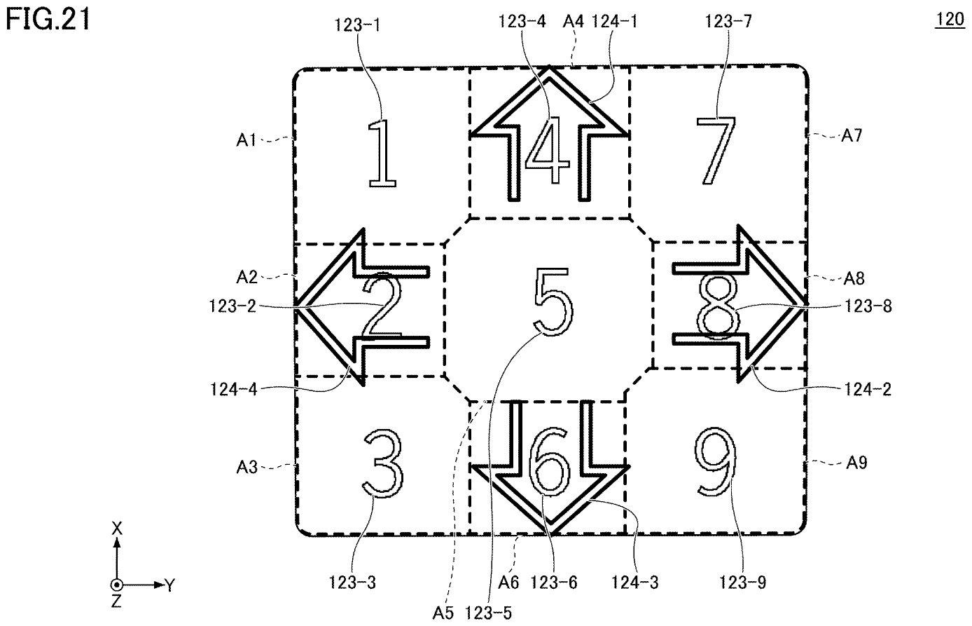

FIG. 17 is a plan view illustrating an input member 120 included in an electrostatic-sensing input device 100 according to a fifth embodiment of the embodiment. FIG. 18 is a plan view illustrating an input member 120 included in an electrostatic-sensing input device 100 according to a sixth embodiment of the embodiment. FIG. 19 is a plan view illustrating an input member 120 included in an electrostatic-sensing input device 100 according to a seventh embodiment of the embodiment. FIG. 20 is a plan view illustrating an input member 120 included in an electrostatic-sensing input device 100 according to an eighth embodiment of the embodiment. FIG. 21 is a plan view illustrating an input member 120 included in an electrostatic-sensing input device 100 according to a ninth embodiment of the embodiment.

In the input member 120 according to the fifth modification illustrated in FIG. 17, each of four decorative portions 124-1, 124-2, 124-3, and 124-4 of the input member 120 may have a triangular shape surrounding a corresponding operation region.

Further, in the input member 120 according to the sixth modification illustrated in FIG. 18, each of decorative portions 124-1, 124-2, 124-3, and 124-4 of the input member 120 may have a circular shape surrounding a corresponding operation region. In addition, in the input member 120 according to the sixth modification illustrated in FIG. 18, the input member 120 may have a fifth decorative portion 124-5 having a circular shape surrounding a central operation region.

Further, in the input member 120 according to the seventh modification illustrated in FIG. 19, each of four decorative portions 124-1, 124-2, 124-3, and 124-4 of the input member 120 may have a linear arrow shape surrounding a corresponding operation region

Further, in the input member 120 according to the eighth modification illustrated in FIG. 20, the input member 120 may include eight decorative portions 124-1, 124-2, 124-3, 124-4, 124-5, 124-6, 124-7, and 124-8 provided corresponding to eight operation regions A4, A8, A6, A2, A7, A9, A3, and A1. In this case, in the input member 120 according to the eighth modification illustrated in FIG. 20, each of the eight decorative portions 124-1, 124-2, 124-3, 124-4, 124-5, 124-6, 124-7, and 124-8 of the input member 120 may have a linear arrow shape surrounding a corresponding operation region.

Further, in the input member 120 according to the ninth modification illustrated in FIG. 21, each of four decorative portions 124-1, 124-2, 124-3, and 124-4 of the input member 120 may have a linear arrow shape that surrounds three sides of a corresponding operation region and in which a portion, located on the center side of the upper portion 122A (that is, on the operation region A5 side), of each decorative portion is discontinuous.

According to the embodiment of the present disclosure, each of the nine electrode portions E1 to E9 has a substantially rectangular shape in a plan view from above (from the positive Z-axis side), but each of the nine electrode portions E1 to E9 may have a polygonal shape other than a circular shape or a rectangular shape, or may have a shape in which corners of the polygonal shape are chamfered.

Although specific embodiments of the present disclosure have been described above, the present disclosure is not limited to these embodiments, and various modifications and changes can be made within the scope of the present disclosure described in the claims.

An electrostatic-sensing input device according to an embodiment of the present disclosure can reduce the manufacturing cost and improve the detection sensitivity of a touch input.

What is claimed is:

1. An electrostatic-sensing input device comprising:
a touch input surface, wherein
the touch input surface includes
a first operation region overlapping a first electrode portion in a plan view,
a first decorative portion having a line shape and a predetermined width, formed of a conductive material, and configured to overlap the first operation region in the plan view,
a second operation region overlapping a second electrode portion in the plan view, and
a second decorative portion having a line shape and a predetermined width, formed of a conductive material, and configured to overlap the second operation region in the plan view, and
the first decorative portion and the second decorative portion are not connected to each other and are not electrically connected to another component.

2. The electrostatic-sensing input device according to claim 1, further comprising:
an input member having the touch input surface and configured to receive a touch input by an operator; and
a sensor sheet including the first electrode portion and the second electrode portion and configured to detect the touch input by being capacitively coupled to an operation body of the operator.

3. The electrostatic-sensing input device according to claim 2, wherein the sensor sheet includes a third electrode portion disposed adjacent to the first electrode portion and to the second electrode portion and configured to generate a detection signal of the touch input by being capacitively coupled to the operating body.

4. The electrostatic-sensing input device according to claim 1, further comprising:
a substrate; and
a light source disposed on the substrate, wherein
an opening is partially provided in each of the first electrode portion and the second electrode portion so as to transmit light emitted from the light source and illuminate the touch input surface.

5. The electrostatic-sensing input device according to claim 2, wherein
the input member includes
a base portion parallel to the sensor sheet, and
a bank portion protruding from the base portion,
the bank portion includes
an upper portion substantially parallel to the base portion and spaced upward from the base portion, and
a side surface portion connecting the upper portion and the base portion and having an inclined surface shape that is inclined with respect to the base portion, and
the first decorative portion and the second decorative portion are disposed on the side surface portion.

6. The electrostatic-sensing input device according to claim 2, wherein
the input member includes
a base portion parallel to the sensor sheet, and
a bank portion protruding from the base portion,
the bank portion includes
an upper portion substantially parallel to the base portion and spaced upward from the base portion, and
a side surface portion connecting the upper portion and the base portion and having a perpendicular surface shape that is perpendicular to the base portion, and
the first decorative portion and the second decorative portion are disposed on the side surface portion.

7. The electrostatic-sensing input device according to claim 1, wherein each of the first decorative portion and the second decorative portion is substantially U-shaped or substantially C-shaped in the plan view.

8. The electrostatic-sensing input device according to claim 7, wherein
the touch input surface includes
a third decorative portion, and
a fourth decorative portion, and
an imaginary line connecting the first decorative portion, the second decorative portion, the third decorative portion, and the fourth decorative portion has a substantially cross-shaped outline in the plan view.

9. The electrostatic-sensing input device according to claim 3, wherein each of the first electrode portion, the second electrode portion, and the third electrode portion has a rectangular shape.

10. The electrostatic-sensing input device according to claim 9, wherein
at least one side of the first electrode portion and at least one side of the third electrode portion are parallel to and oppose each other, and
at least one side of the second electrode portion and at least one side of the third electrode portion are parallel to and oppose each other.

11. The electrostatic-sensing input device according to claim 1, wherein external dimensions of the first operation region are larger than external dimensions of the first electrode portion.

12. The electrostatic-sensing input device according to claim 1, wherein the first decorative portion has a closed-loop shape.

13. The electrostatic-sensing input device according to claim 1, wherein a gap is provided between the first decorative portion and the second decorative portion.
